(19) United States
(12) Patent Application Publication
(10) Pub. No.: US 2018/0130918 A1
(43) Pub. Date: May 10, 2018

(54) METHOD AND DEVICE FOR IMPROVING POWER GENERATION EFFICIENCY OF SOLAR CELL ON UNIT ERECTED AREA

(71) Applicant: Chung-Cheng CHANG, Keelung (TW)

(72) Inventor: Chung-Cheng CHANG, Keelung (TW)

(21) Appl. No.: 15/804,370

(22) Filed: Nov. 6, 2017

(30) Foreign Application Priority Data
Nov. 7, 2016 (TW) 105136112

(51) Int. Cl. H01L 31/043; H01L 31/0468; H01L 31/048; H01L 31/054

(52) U.S. Cl. CPC H01L 31/043; H01L 31/0547; H01L 31/048; H01L 31/0468

(57) ABSTRACT

The present invention provides a method for improving power generation efficiency of solar cell on unit erected area, comprising: providing a base solar cell and a set of light transmitting solar cell, the set of light transmitting solar cell is configured on a light receiving surface of the base solar cell; wherein the set of light transmitting solar cell comprises at least one light transmitting solar cell and the light transmitting solar cell has a partial light transmission property. By the technical features of the present invention, we can improve the power generation efficiency 2 times and up. Furthermore, the present invention erects the solar cell in an uneven shape on fixed solar cells erected area, therefore improving power generation efficiency on unit solar cells erected area.

### CROSS-REFERENCE TO RELATED APPLICATION

This application claims the priority of Taiwanese patent application No. 105136112, filed on Nov. 7, 2016, which is incorporated herewith by reference.

### BACKGROUND OF THE INVENTION

### 1. Field of the Invention

The present invention is related to a solar cell erecting method, more specifically, the present invention is related to method and device for improving power generation efficiency of solar cell on unit erected area.

### 2. The Prior Arts

Currently, the power source people using in daily life is still mainly petrochemical energy. Although the petrochemical energy is not at a crisis of immediate depletion yet, but since people overuse the petrochemical energy and emission the carbon dioxide, causing the greenhouse effect and the earth's temperature rises. Moreover, crude oil prices are quite volatile in recent years; therefore, the search for alternative energy has become a top priority.

Solar energy is a renewable energy which is inexhaustible in nature. Compared with the currently mainstream of petrochemical energy, solar energy is energy with more environmentally friendly and cleaner. Although the power efficiency of solar cell has been improved but there are still restrictions. Especially in a limited erected area, the power efficiency of solar cell is also limited. Thus, the application of solar cells is also limited, such as a conveyance using solar cell as a power source. In the case of cars, the solar panels will make up a large portion of the solar-powered car, creating obstacles to travel and generating insufficient power. Aircraft using solar cells have the same problem. In addition, even in the home balcony or roof are erected solar cells, most of the balcony or roof area cannot provide sufficient power supply.

Solar energy is relatively environmentally friendly and clean energy currently. However, in the solar photovoltaic field, because the daily sunshine duration is limited and solar cells must be used to set up on a larger space. In today's high land costs, how to set up solar cells in a limited area and get the maximum power generation or power generation efficiency, it is the problem that people eagerly awaited to be solved.

### SUMMARY OF THE INVENTION

The inventor of the present invention have made intensive studies on the problem that the solar cell is insufficient in power generation per unit area (“Erection area” means the area occupied by the traditional single-layer tiled of solar cells), and provide a method for improving power generation or power generation efficiency of solar cell on unit erected area. The power generation efficiency here is the maximum output power is divided by the incident power of the sunlight on unit erected area. This method is applicable to any kind of solar cell. This concept can use a three-dimensional structure of light transmitting solar cell and three-dimensional uneven shape (such as curved surface) solar cell to accomplish. The three-dimensional structure comprises a base solar cell and a set of light transmitting solar cell, the set of light transmitting solar cell is configured on a light receiving surface of the base solar cell; wherein the set of light transmitting solar cell comprises at least one light transmitting solar cell, and the light transmitting solar cell has a partial light transmission property.

The light transmitting solar cell or the base solar cell can employ the light transmitting solar cell panel with light transmitting holes, the partial light transparent solar cell panel or their combination. The set of light transmitting solar cell may have multiple layers structure. A gap can be formed among the solar cells in the set of light transmitting solar cell and the base solar cell. The light transmitting solar cell panel with light transmitting hole, its light transmitting hole's size and shape, such as big holes or tiny holes and shape of circular or square, may be designed by considering the diffraction and scattering of sunlight. For example, the shape of the light transmitting hole is selected from a group consisting of a circle, a rhombus, a polygon, an oval, a rectangle and the like and an irregular shape. The proportion of the area occupied by the light transmitting holes and the light transmitting hole's size can be optimized by processing and operating environment. The method for making a light transmitting solar cell panel with light transmitting holes can be made by processes of etching, MEMS, assembly, molding, etc. It is easy to complete for a skilled in the art. In addition, we may use existed process to let a solar cell to be partial light transmitted. For example, a process for thinning the solar cell (such as a thin-film solar cell made by MEMS technique) or a method for making a solar cell with a translucent material. Further, the three-dimensional uneven shape, such as curved surface, can also achieve the similar result. The three-dimensional uneven shape solar cell erects on a fixed erected area can scatter the light received on the solar cell panel to bigger area of solar cell panel, thus increases power generation or power generation efficiency on unit erected area. The uneven shape can be a shape of sin wave, a square wave, a triangular wave, a sphere, a cone, a column, a prismoid, a polyhedron, a curved body, a barrel, a ring, or any combination thereof. The uneven shape mainly scatters sunlight to increase the received light on unit area. The three-dimensional uneven shape solar cell can be extended out, such as in a periodic way or in an arrangement way, as a solar cell panel with large surface. The three-dimensional uneven shape solar cell can be served as the base solar cell, it also can be served as a solar cell of the set of light transmitting solar cell, that is, it can combine with the light transmitting solar cell in various forms. In the erected device of the present invention, an appropriate gap can be formed among each solar cell, that is, an appropriate gap can be formed between the base solar cell and the set of light transmitting solar and among each light transmitting solar cell to form three-dimensional structure. As a result, the three-dimensional structure can increase power generation or power generation efficiency on unit erected area. The features of the light transmitting hole, the partial light transparent property, the three-dimensional uneven shape and their any combination may include in one solar cell. The base solar cell and the solar cells of the set of light transmitting solar cell can employ the solar cell having the light transmitting hole(s), the partial light transparent property and the three-dimensional uneven shape to build various 3D structures. It all can achieve the aim of the present invention. This concept can be achieved through the 3D structure of the set of light transmitting solar cell, the solar cell with uneven shape (such as curved surface) and their combination. The “solar cell” in the specification can be any solar cell. For example, a solar cell made from a semiconductor material, an inorganic material or an organic material, the semiconductor material is a silicon material, a single element semiconductor material or a compound semiconductor material; or such as a thin film solar cell or thick film solar cell; or such as single crystalline, polycrystalline or amorphous solar cells.

In an embodiment of the present invention, a gap is between the base solar cell and the set of light transmitting solar cell. The gap is preferred at least 1 cm.

In an embodiment of the present invention, further wetting or immersing the base solar cell and the set of light transmitting solar cell into a liquid.

In an embodiment of the present invention, the set of light transmitting solar cell comprises at least two light transmitting solar cells; a gap is between each two light transmitting solar cells; the gap is preferred at least 1 cm.

In an embodiment of the present invention, the base solar cell and the light transmitting solar cell are in panel shape or three-dimensional uneven shape. The uneven shape comprises a shape of a sine wave, a square wave, a triangular wave, a sphere, a cone, a column, a prismoid, a polyhedron, a curved body, a barrel, a ring, or any combination thereof. The three-dimensional uneven shape can be extended out, such as in a periodic way or in an arrangement way, as a solar cell panel with large surface.

In an embodiment of the present invention, the light transmitting solar cell has a plurality of light transmitting holes and therefore has partial light transmitting property. The light transmitting hole has a shape selected from the group consisting of circular, rhombic, polygonal, oval, rectangular, and irregularly shaped.

The present invention also provides a device for improving power generation or power generation efficiency of solar cell on unit erected area (this concept can be achieved through the 3D structure of the set of light transmitting solar cell, the solar cell with uneven shape (such as curved surface) and their combination), comprising: a base solar cell and a set of light transmitting solar cell, the set of light transmitting solar cell is configured on a light receiving surface of the base solar cell; wherein the set of light transmitting solar cell comprises at least one light transmitting solar cell and the light transmitting solar cell has a partial light transmission property.

The light transmitting solar cell or the base solar cell can employ the light transmitting solar cell panel with light transmitting hole, the partial light transparent solar cell panel or their combination. The set of light transmitting solar cell may have multi-layer structure. A gap can be formed among the solar cells in the set of light transmitting solar cell and the base solar cell. Further, the three-dimensional uneven shape, such as curved surface, can also achieve the similar result. The three-dimensional uneven shape solar cell erects on a fixed erected area can scatter the light received on the solar cell panel to bigger area of solar cell panel, thus increases power generation or power generation efficiency on unit erected area. The three-dimensional uneven shape solar cell can be served as the base solar cell; it also can be served as a solar cell of the set of light transmitting solar cell or the light transmitting solar cell. An appropriate gap can be formed among each solar cell, that is, an appropriate gap can be formed between the base solar cell and the set of light transmitting solar and among each light transmitting solar cell to form three-dimensional structure. As a result, the three-dimensional structure can increase power generation or power generation efficiency on unit erected area. The features of the light transmitting hole, the partial light transparent property, the three-dimensional uneven shape and their any combination may include in a solar cell. The base solar cell and the solar cells of the set of light transmitting solar cell can employ the solar cell having the light transmitting hole, the partial light transparent property and the three-dimensional uneven shape to build various 3D structures. It all can achieve the aim of the present invention. This concept can be achieved through the 3D structure of the set of light transmitting solar cell, the solar cell with uneven shape (such as curved surface) and their combination. The “solar cell” in the specification can be any solar cell. For example, a solar cell made from a semiconductor material, an inorganic material or an organic material, the semiconductor material is a silicon material, a single element semiconductor material or a compound semiconductor material; or such as a thin film solar cell or thick film solar cell; or such as single crystal, polycrystalline or amorphous solar cells. In the 3D structure of the light transmitting solar cells, sunlight can transmit the solar cell and receive the second layer or multi layers of solar cells.

In an embodiment of the present invention, a gap is between the base solar cell and the set of light transmitting solar cell. The gap is preferred at least 1 cm.

In an embodiment of the present invention, further comprising a container and a liquid, the liquid is in the container and thereby the base solar cell and the set of light transmitting solar cell are wetted or immersed into the liquid.

In an embodiment of the present invention, the set of light transmitting solar cell comprises at least two light transmitting solar cells; a gap is between each two light transmitting solar cells; the gap is preferred at least 1 cm. The base solar cell and the light transmitting solar cell are in panel shape or three-dimensional uneven shape such as a shape of a sine wave, a square wave or a triangular wave.

In an embodiment of the present invention, the light transmitting solar cell has a plurality of light transmitting holes and therefore has a partial light transmission property; wherein the light transmitting hole has a shape selected from the group consisting of circular, rhombic, polygonal, oval, rectangular, and irregularly shaped.

The present invention also provides a method for improving power generation or power generation efficiency of solar cell on unit erected area, comprising configuring a solar cell panel in a three-dimensional uneven shape; the three-dimensional uneven shape can increase solar cells light receiving area on unit erected area; light received on the solar cell panel is scattered to bigger area of solar cell panel thus decreases in illuminance (compare with panel shape solar cell). The uneven shape may be any of three-dimensional geometries, including a sine wave, a square wave, a triangular wave, a sphere, a cone, a column, a prismoid, a polyhedron, a curved body, a barrel, a ring, or any combination thereof. The uneven shape solar all solar cell erect on a fixed erected area can scatter the light received on the solar cell panel to bigger area of solar cell panel, thus increase power generation or power penetration efficiency on unit erected area. The three-dimensional uneven shape solar cell can be extended out, such as in a periodic way, arbitrary extension or in an arrangement way, as a solar cell panel with large surface.

By the features of the present invention, the power generation or power generation efficiency is improved on fixed light receiving area. For solar cell power generation in a limited area, it is very practical for generating more power. For example, the solar cell outside the house, on the roof, inside the house, on a conveyance such as a car, a plane and a spacecraft and a portable device such as a mobile phone and a watch. The present invention has wide range of applications, thus increase the availability of solar power. Thus solar power plants can be installed at the same site and get more power output.

The method of present invention no needs to add auxiliary system which may decrease light exposure or increase the cost. The method include the transmitting solar cell with light transmitting holes, the partial transparent solar cell, the solar cell has uneven shape or their combinations. Thus the solar cell erects on a fixed erected area can scatter the light received on the solar cell panel to bigger area of solar cell panel, thus increases power generation or power generation efficiency on unit erected area. This concept can be achieved through the 3D structure of the set of light transmitting solar cell, the solar cell with uneven shape (such as curved surface) and their combination. In the 3D structure of the light transmitting solar cells, sunlight can transmit the solar cell and receive the second layer or multi layers of solar cells. Thus, the sun light can distribute to plural of solar cells to generate power, and therefore improve the power generation or power generation efficiency on unit sunlight illumination area. The device builds with 3D deployment can further improve the power generation efficiency. Further, the three-dimensional uneven shape, such as curved surface, can also achieve the similar result. The three-dimensional uneven shape solar cell erects on a fixed erected area can scatter the light received on the solar cell panel to bigger area of solar cell panel, thus increases power generation or power generation efficiency on unit erected area.

The preferred embodiments described below are disclosed for illustrative purpose but to limit the modifications and variations of the present invention. Thus, any modifications and variations made without departing from the spirit and scope of the invention should still be covered by the scope of this invention as disclosed in the accompanying claims.

### BRIEF DESCRIPTION OF THE DRAWINGS

The present invention will be apparent to those skilled in the art by reading the following detailed description of a preferred embodiment thereof, with reference to the attached drawings, in which:

FIGS. 1A-1C show the changes of output voltage V, current I and power P of the solar cell under various light illuminance;

FIGS. 1D-1F show the changes of output voltage V, current I and power P of the solar cell under various light illuminance in another independent experiment;

FIGS. 2A-2C show the changes of output voltage, current and power of the solar cell during 0-10 minutes under 90000±500 lux, 32° C.;

FIG. 3A shows the structure for improving power generation efficiency of solar cell on fixed erected area of the present invention;

FIG. 3B shows another embodiment of the structure of improving power generation efficiency of solar cell on unit/fixed erected area of the present invention; wherein a gap is between each solar cell panel;

FIG. 4A is a schematic diagram illustrating the structure for improving power generation efficiency of solar cell on fixed erected area of the present invention; wherein employing solar cells with light transmitting holes;

FIG. 4B is a schematic diagram illustrating the structure for improving power generation efficiency of solar cell on fixed erected area of the present invention; wherein employing solar cells with light transmitting holes and a gap is between each solar cell panel;

FIG. 4C is a schematic diagram illustrating the structure for improving power generation efficiency of solar cell on fixed erected area of the present invention; wherein employing solar cells with rhombus light transmitting holes and deploying in different directions;

FIG. 5A is a schematic diagram illustrating solar cell in sine wave shape;

FIG. 5B is a schematic diagram illustrating solar cell in triangle wave shape;

FIG. 5C is a schematic diagram illustrating the structure for improving power generation efficiency of solar cell on fixed erected area of the present invention; wherein employing multiple solar cells in triangle wave shape;

FIG. 6A is a schematic diagram illustrating the structure for improving power generation efficiency of solar cell on fixed erected area of the present invention; wherein the structure further comprises a container and a liquid;

FIG. 6B shows the structure for improving power generation efficiency of solar cell on fixed erected area of the present invention; wherein the structure further comprises a container and a liquid, and a gap is between the base solar cell and the set of light transmitting solar cell;

FIG. 6C is a schematic diagram illustrating a structure similar with FIG. 6B and further comprising a light transmitting solar cell; wherein a gap is between each two light transmitting solar cells;

FIG. 6D is a schematic diagram illustrating a structure similar with FIG. 6C and further comprising a light transmitting solar cell;

FIG. 7A is a schematic diagram illustrating the imitation of the solar cell with rhombus light transmitting holes (an anti-slip mat);

FIGS. 7B-7E show the change of illuminance, output voltage, current and power of the solar cell covered with 0-4 imitations of the embodiment 1;

FIGS. 8A-8C show the illuminance, output voltage, current and power of the solar cell panel while increasing the gap between imitation(s) and the solar cell panel of the embodiment 2;

FIGS. 9A-9C show the output voltage, current and power of the solar cell while various gaps between imitation(s) and the solar cell of the embodiment 3;

FIGS. 10A-10C show the output voltage, current and power of the solar cell while increasing the imitations number of the embodiment 4;

FIGS. 11A-11C show the output voltage, current and power of the solar cell while increasing the gap between imitation(s) and the solar cell of the embodiment 5;

FIGS. 12A-12C show the output voltage, current and power of the solar cell while increasing the imitations number and the gap between imitation(s) and the solar cell of the embodiment 5;

FIGS. 13A-13C show the output voltage, current and power of the solar cell while increasing the imitations number and the gap between imitation(s) and the solar cell of the embodiment 6;

FIGS. 14A-14C shows the repeat experimental result of FIGS. 13A-13C under different illuminance;

FIGS. 15A-15C show the output voltage, current and power of the solar cell without imitation at 0, 5 and 10 mins under sun light;

FIGS. 16A-16C show the output voltage, current and power of the solar cell covered with one imitation (without gap) at 0, 5 and 10 mins under sun light of the embodiment 7;

FIGS. 17A-17C show the output voltage, current and power of the solar cell covered with two imitations at 0, 5 and 10 mins under sun light of the embodiment 7;

FIG. 18 is a schematic diagram illustrating the solar cell is employed in different positions to imitate the solar cell with uneven shape;

FIGS. 19A-19C show the output voltage, current and power of the solar cell (at position 1 in FIG. 18) under the illuminance of 10000 lux, 15000 lux and 60000 lux;

FIGS. 20A-20C show the output voltage, current and power of the solar cell (at position 2 in FIG. 18) under the illuminance of 10000 lux, 15000 lux and 60000 lux;

FIGS. 21A-21C show the output voltage, current and power of the solar cell (at position 3 in FIG. 18) under the illuminance of 10000 lux, 15000 lux and 60000 lux;

FIG. 21D shows the output power of the solar cell at position 1 in FIG. 18 compared with the total output power of the solar cells at position 2 and 3 in FIG. 18;

FIGS. 22A-22D shows the output voltage, current and power of the solar cell with increasing imitations number of the embodiment 9;

FIGS. 23A-23C show the ratio change of P/P₀, lux/lux₀ and P/lux of the embodiment 9;

FIGS. 24A-24D show the illuminance, output voltage, current and power of the solar cell in three circumstances of the embodiment 10;

FIGS. 25A-25D shows the output voltage, current and power and P/P₀ of the solar cell with increasing imitations number of the embodiment 11;

FIG. 26A is a schematic diagram illustrating the structure comprises four layer (one screen panel and one glass slide for each layer) to imitate mixed type light transmitting solar cell panels; wherein there is no gap between base solar cell and the set of light transmitting solar cell as well as between each of light transmitting solar cells;

FIG. 26B is a schematic diagram illustrating the structure comprises two layer (one screen panel and one glass slide for each layer) to imitate mixed type light transmitting solar cell panels; wherein there is a gap between base solar cell and the set of light transmitting solar cell as well as between each of light transmitting solar cells;

FIG. 26C is a schematic diagram illustrating the structure comprises two layer (one screen panel and six glass slides for each layer) to imitate mixed type light transmitting solar cell panels;

FIGS. 27A-27D show the illuminance, output voltage, current and power of the solar cell in five circumstances of the embodiment 12;

FIGS. 27E-27G show the results of lux/lux₀, P/Po and P/LUX of the embodiment 12;

FIGS. 28A-28D show the illuminance, output voltage, current and power of the solar cell in three circumstances of the embodiment 13;

FIGS. 29A-29D show the illuminance, output voltage, current and power of the solar cell in three circumstances of the embodiment 14;

FIGS. 30A-30E is a schematic diagram illustrating the shapes of solar cell can be employed in the structure for improving power generation efficiency of solar cell on fixed erected area of the present invention; there is a shape of prismoid, polyhedron, curved body, barrel and a ring, receptively;

FIG. 31A is a schematic diagram illustrating the structure for improving power generation efficiency of solar cell on fixed erected area of the present invention; wherein the barrel shape solar is extended out in a periodic way.

FIGS. 31B and 31C is a schematic diagram illustrating the structure for improving power generation efficiency of solar cell on fixed erected area of the present invention; wherein the sphere (31B) and ring (31C) solar is extended out in a array arrangement way.

### DETAILED DESCRIPTION OF THE PREFERRED EMBODIMENT

As used herein, “approximately” shall generally mean within 20 percent, preferably within 10 percent, and more preferably within 5 percent of a given value or range. Numerical quantities given herein may vary depending on the different instruments or different measurement methods. Thus, numerical quantities given herein are approximate, meaning that the term “approximately” can be inferred if not expressly stated.

In the embodiments of the present invention, we use an imitation to imitate the solar cell with light transmitting holes. The imitation is a thin anti-slip mat having rhombus holes and is also called a “screen penal”. We also use an imitation to imitate the solar cell with high transmittance, such as glass slide. The imitations used in the embodiments have been described in each embodiment, and the imitation is a thin anti-slip mat if not expressly stated.

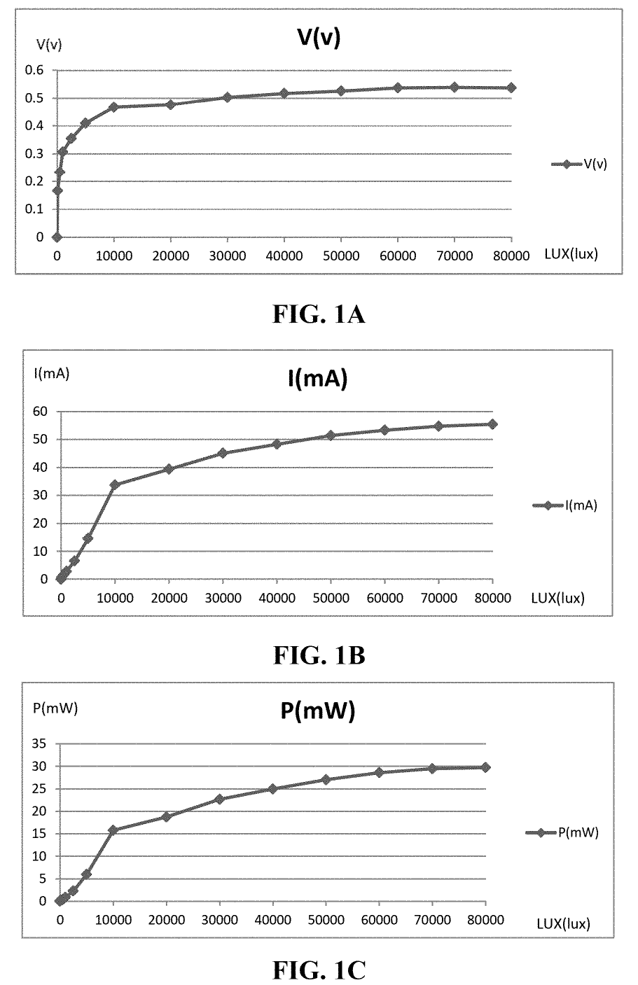

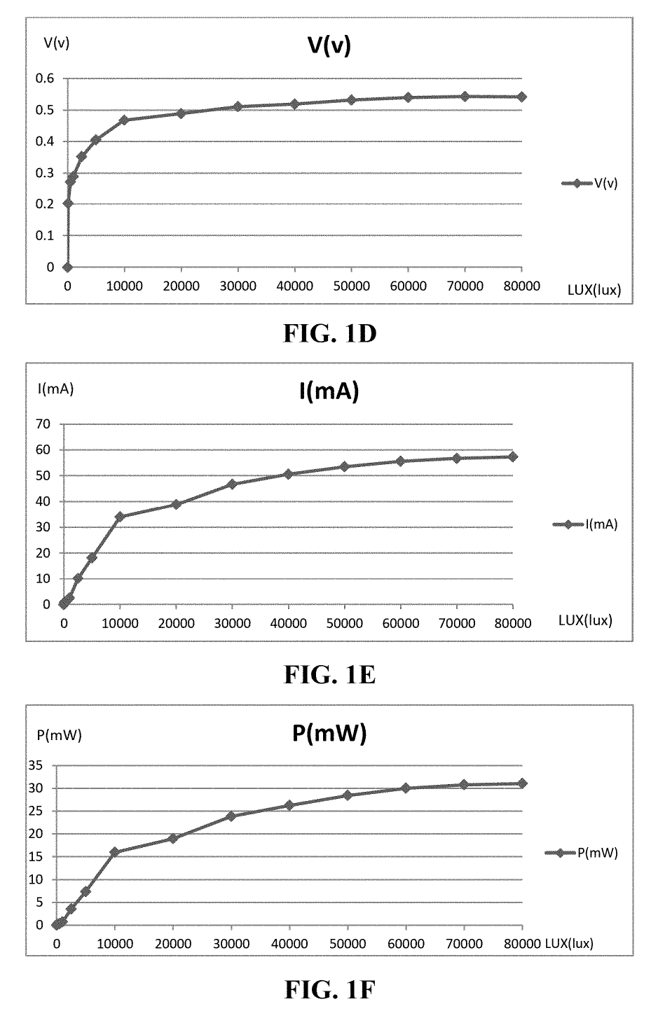

FIGS. 1A-1C show the output voltage V, current I and power P of 4×4 cm single crystalline silicon solar cell (purchased from Unitech Co. and packaged by ourselves) under various sun illuminance. For ease of calculation, we define P=I×V. Although the calculated power P would slightly higher than the actual value, but it won't affect the outcome of the judgment since the comparison of data are relative. In FIGS. 1A-1C, the output current, voltage and power showed saturating with the increase of sun illuminance. The environment temperature was 30° C. Through FIGS. 1A-1C, the power efficiency (V, I and P) of solar cell and the illuminance (LUX, unit: lux) are not a linear relationship. The proportional power efficiency of solar cells is smaller in high illuminance than in low illuminance, that is, too high illuminance would suppress the power efficiency of solar cells.

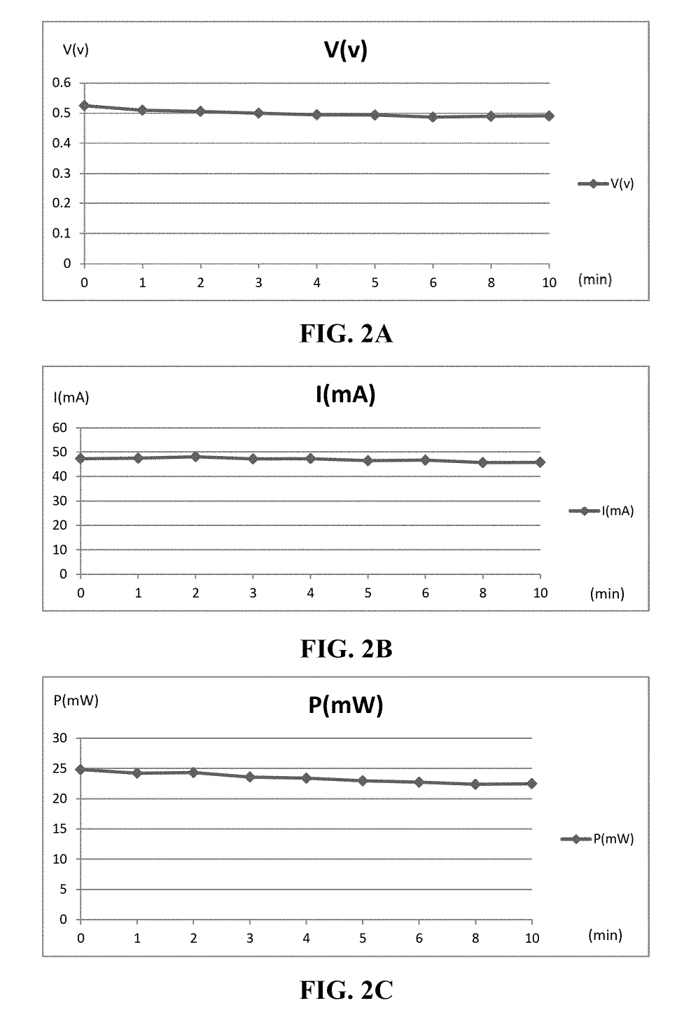

FIGS. 1D-1F shows the results of another experiment, the repeat experiment of FIGS. 1A-1C. The results are similar with FIGS. 1A-1C. The environment temperature is 30° C. High illuminance sunlight rise the temperature of the solar cell and decrease the power efficiency. FIGS. 2A-2C show the output voltage, current and power values of the solar cell various with time under 32° C., 90000±500 lux sunlight. In those figures, the output voltage, current and power values show a slightly declining trend at 10 minutes since the high illuminance and long duration. In summary, too high illuminance would lead the power efficiency of solar cells have a declining trend.

FIGS. 1A-1F show that P/lux ratio under high sunlight (40000 lux and up) gradually saturated. The preferred P/lux ratio is at 10000˜40000 lux. The more preferred P/lux ratio is at 500˜10000 lux, but the output power is low since the illuminance low. The P/lux ratio is not good while the illuminance is under 500 lux. According to the result above, the sunlight-electrical energy converting efficiency of the solar cell is better while under 10000 lux˜40000 lux sunlight. The sunlight-electrical energy converting efficiency of the solar cell is getting worse when sunlight is over 40000 lux. Thus, the concept of the invention is that equally distributing the strong sunlight to other solar cells. In this way, more electrical energy can be generated on fixed light received area, although the more solar cells are employed. In a limited erected area, the power efficiency of solar cell is also limited. Thus, the application of solar cells is also limited, such as a conveyance using solar cell as a power source. In the case of cars, the solar panels will make up a large portion of the solar-powered car, creating obstacles to travel and still generating insufficient power. Aircraft using solar cells have the same problem. In addition, solar-powered watch or cell phone also have the same problem—generating insufficient power on unit light receiving area. Although we can solve this problem by using high efficiency solar cell, but this solution will substantial increase in costs. If we consider the cost, the high efficiency solar cell is still unrealistic. Thus, the method of the present invention is the solution to solve this problem.

The present invention is focused on distributing the over strong light to other solar cell. It is different from current methods such as non-distribution or even focusing the sunlight. The low-cost solar cells are especially suitable for the method of the present invention. The method of the present invention is useful in the case of limited light received area and high power consumption. The present invention uses more solar cells to form the structure of light-distributing, multi-layer, three-dimension or uneven shape (such as curved surface) and significantly increase the generated power.

Thus, the present invention provides a method for improving power generation or power generation efficiency of solar cell on unit erected area, comprising: providing a base solar cell and a set of light transmitting solar cell, the set of light transmitting solar cell is configured on a light receiving surface of the base solar cell; wherein the set of light transmitting solar cell comprises at least one light transmitting solar cell and the light transmitting solar cell has a partial light transmission property.

It may be a gap between the base solar cell and the set of light transmitting solar cell and between each two light transmitting solar cells. Second, the uneven shape solar cell erects on a fixed erected area can scatter the light received on the solar cell panel to bigger area of solar cell panel, thus increases power generation or power generation efficiency on unit erected area. The three-dimensional uneven shape solar cell can be served as the base solar cell or the light transmitting solar cell. Third, the set of light transmitting solar cell may include solar cells with partial light transmitting holes, partial transparent and/or uneven shape. The base solar cell also may include solar cell with partial light transmitting holes, partial transparent and/or uneven shape. The base solar cell and the set of light transmitting solar cell can be form a multi-layer 3 dimensional solar cell set, thereby improving power generation or power generation efficiency of solar cell on fixed erected area.

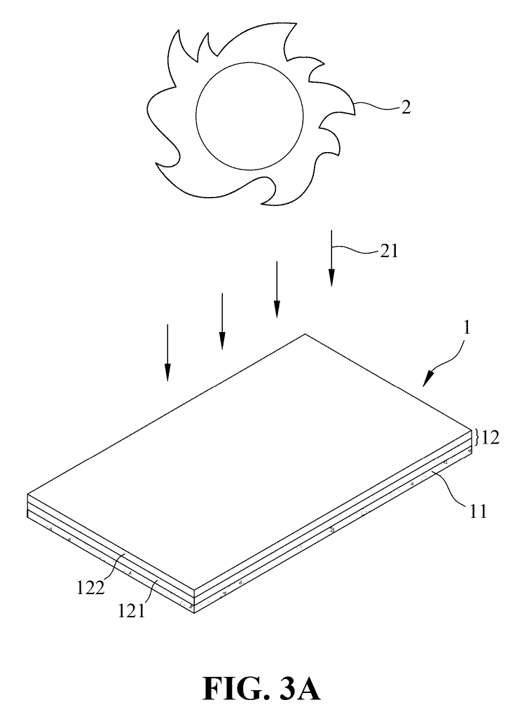

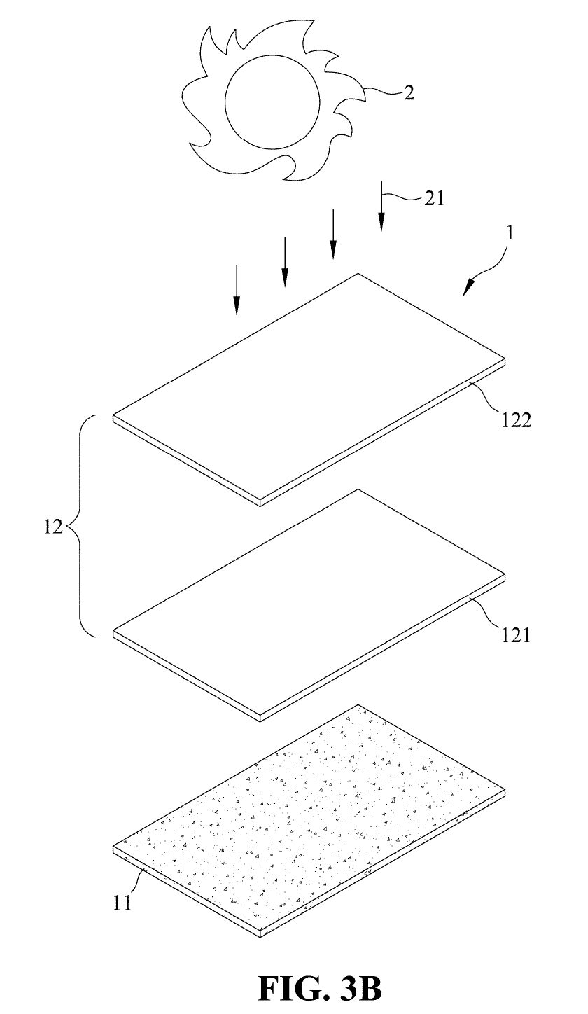

Also, the present invention provides a device for improving power generation or power generation efficiency of solar cell on unit erected area, shown as FIG. 3A. In the figure, the device 1 comprising: a base solar cell 11 and a set of light transmitting solar cell 12, are configured from far to near the sun 2, that is, the set of light transmitting solar cell 12 is configured on a light receiving surface of the base solar cell 11; wherein the set of light transmitting solar cell 12 comprises light transmitting solar cells 121,122 and the light transmitting solar cells 121,122 has partial light transmission property. Thus, after the sunlight provide the light transmitting solar cell 122 to generate power, part of sunlight 21 transmits the light transmitting solar cell 122 to transmits the light transmitting solar cell 121, than optionally goes through more light transmitting solar cell and finally reach the base solar cell 11 for power generating. The base solar cell 11 can be light transmitted or opaque. We can choose the solar cell which has better power generation efficiency. Preferably, “partial light transmission property” means transmittance more than 5%.

Please refers to FIG. 3B, the figure shows another embodiment of the device for improving power generation or power generation efficiency of solar cell on unit/fixed erected area of the present invention. The device 1 comprises a base solar cell 11 and a set of light transmitting solar cell 12, are configured from far to near the sun 2; wherein the set of light transmitting solar cell 12 comprises at least a light transmitting solar cell 121,122, the light transmitting solar cell 121,122 has a partial light transmission property. The base solar cell 11 and the set of light transmitting solar cell 12 can have an appropriate distance (gap) in between. The distance can be optimized according to the types and sizes of solar cells.

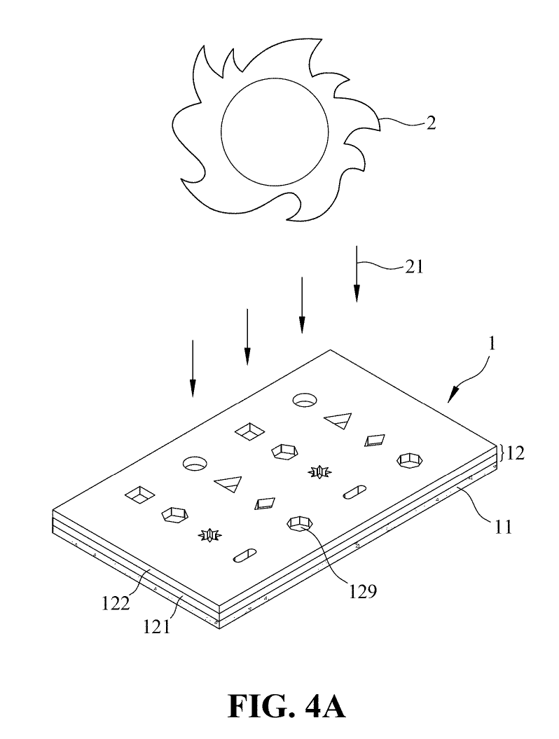

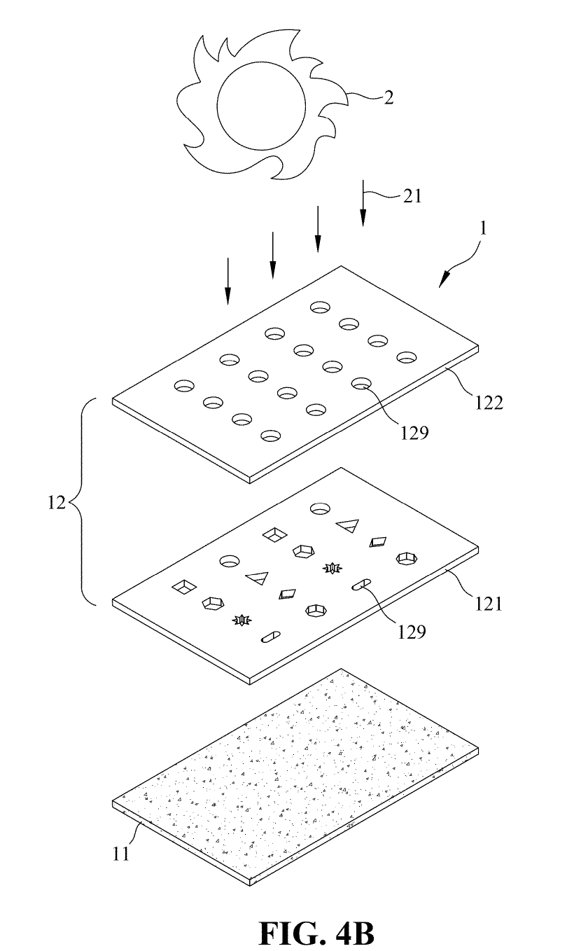

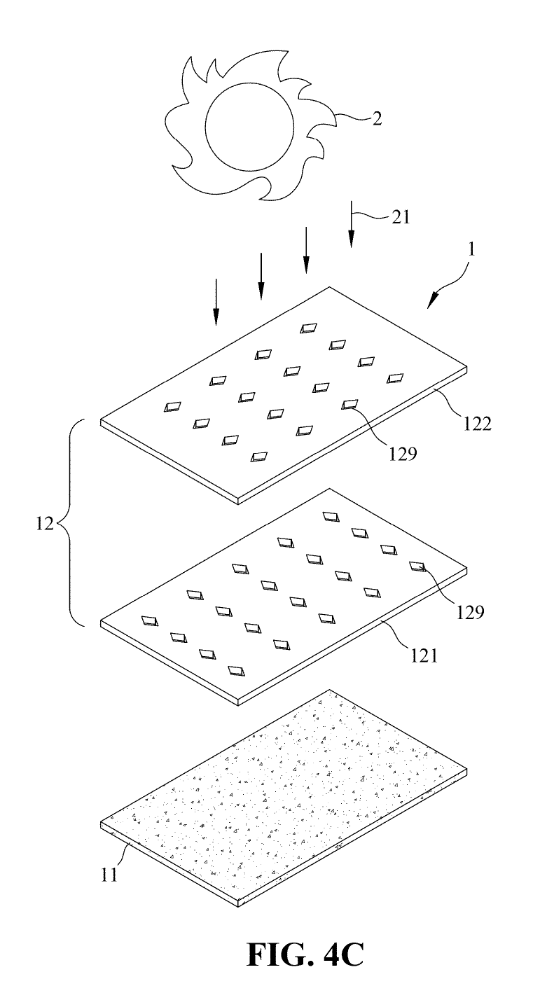

We may use several methods to let a solar cell to be partial light transmitted. For example, a process for thinning the solar cell or a method for making a solar cell with a translucent material, such as a thin-film solar cell made by MEMS technique. Further, please refer to FIG. 4A, in one embodiment of the present invention, the light transmitting solar cell 121,122 have a plurality of light transmitting holes 129, thereby having a partial light transmission property. The light transmitting hole 129 has a shape selected from the group consisting of circular, rhombic, polygonal, oval, rectangular, and irregularly shaped. The shape of the light transmitting hole 129 is not limited, it is only necessary that the transparent solar cells 121,122 have light transmission property. The shape or size of the light transmitting hole 129, such as a big hole or a small hole or shape of circular or square, can be designed according to the diffraction and scattering effect of the sunlight 21. As shown in FIG. 4B, the base solar cell 11 has a distance away from the set of light transmitting solar cell 12. The base solar cell 11 and the light transmitting solar cell 121,122 may employ the solar cell with light transmitting holes 129. The shape of light transmitting holes 129 on the light transmitting solar cell 121 and the light transmitting solar cell 122 can be the same or different. The figure is an example of the shape of light transmitting holes 129 on the light transmitting solar cell 121 and the light transmitting solar cell 122 is different (circular, irregular, triangular, etc.). Please refer to FIG. 4C, shows the shape of the light transmitting holes 129 is rhombus and the shape of light transmitting holes 129 on the light transmitting solar cell 121 and the light transmitting solar cell 122 is the same but in different directions. As shown in the figure, the shape of the light transmitting holes 129 on the upper and below light transmitting solar cell can be staggered. The shape of the light transmitting holes 129 of the entire light-transmitting solar cells 121, 122 can be made uniform; it also can be in different shape on the entire light-transmitting solar cells 121, 122. It is only necessary that partial sunlight 21 can go through and reach the lower solar cell. Preferably, we can adjust the size of the light transmitting holes 129 to let the light receive the solar cell uniformly. The shape of the light transmitting holes 129 on different layer of solar cell can be complementary to each other, for example, after the position of the light transmitting holes 129 on the light transmitting solar cell 122 are fixed, the light transmitting holes 129 on the light transmitting solar cell 121 do not be located just below the light transmitting holes 129 on the light transmitting solar cell 122, they can be shifted to the position nearby and therefore the light can be uniformly among each layer of solar cell. The percentage of area occupied, shape or size can be optimized according to process and environmental requirements. The light transmitting solar cell 121,122 can be a solar cell with light transmitting holes 129, a partial transparent solar cell or a solar cell combination thereof.

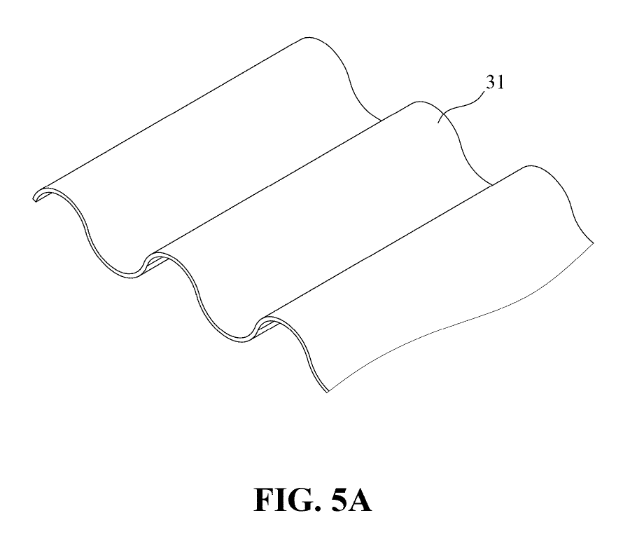

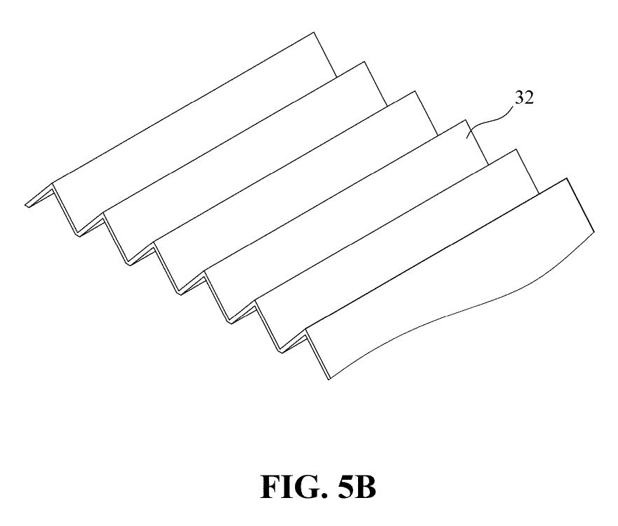

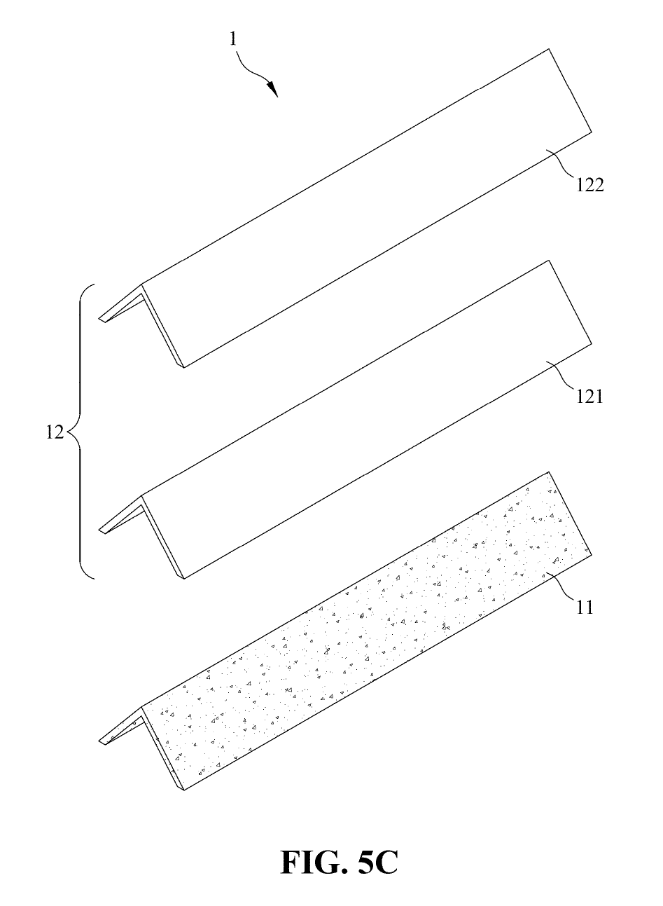

In an embodiment of the present invention, the set of light transmitting solar cell 12 comprises at least two light transmitting solar cells 121,122, each separated by at least 1 cm. The distance of each light transmitting solar cell 121,122 can be adjusted and optimized according to the type, size and environment (light scattering and diffraction status) of the solar cells. The base solar cell 11 and the light transmitting solar cell 121,122 are in panel shape (FIGS. 3A-3B and 4A-4C) or a shape of a sine wave (as the sine wave shape solar cell panel 31 in FIG. 5A), a square wave, a triangular wave (as the triangular wave shape solar cell panel 32 in FIG. 5B; and as another embodiment which utilizes multi-layer triangular wave shape solar cell panel 11,12 of the device 1 in FIG. 5C). The base solar cell 11 and the light transmitting solar cell 121,122 which are in sine wave, square wave or triangular wave shape reduce light receiving amount in one panel and scatter part of light to other solar cell. When we construct the device, the ridge line of the triangular wave shape solar cells preferably aligns the sun, thereby increasing power generation or power generation efficiency.

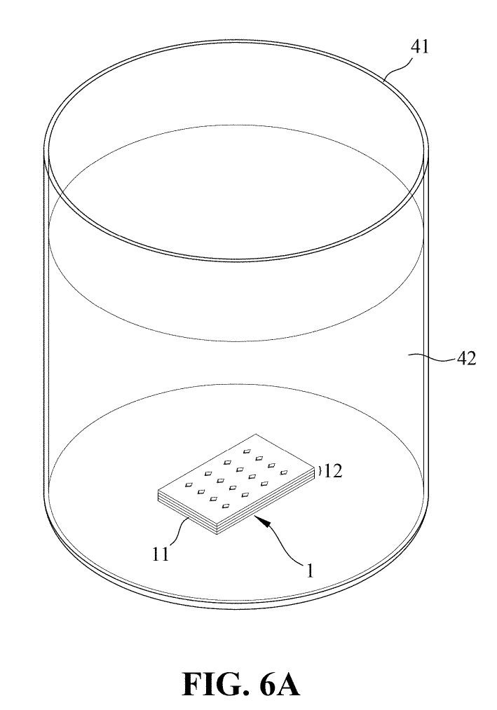

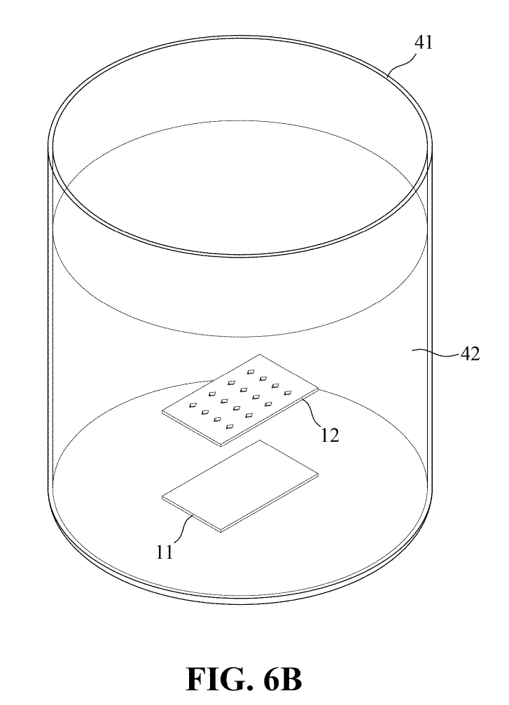

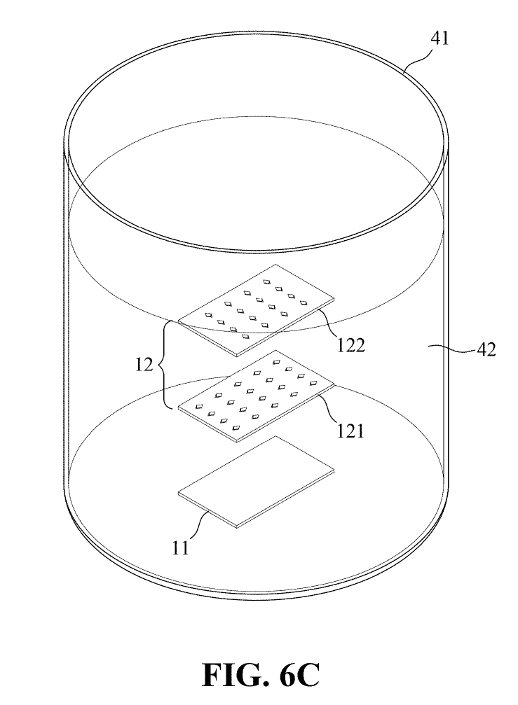

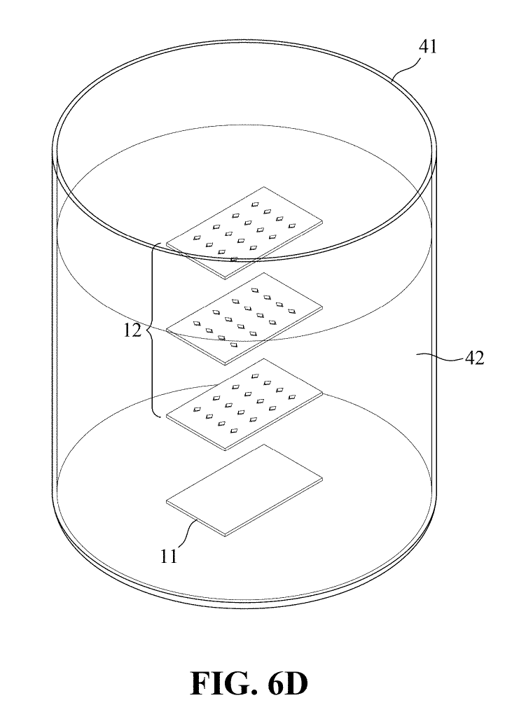

Please referred to FIG. 6A, the figure shows in an embodiment, the device further comprises a container 41 and a liquid 42, the liquid 42 is in the container 41 and thereby the base solar cell 11 and the set of light transmitting solar cell 12 are wetted or immersed into the liquid. In this embodiment, a gap is between the base solar cell 11 and the set of light transmitting solar cell 12 to increase power generation or power generation efficiency (FIG. 6B). Further, in FIG. 6C, a gap may be between the light transmitting solar cells 121,122 in the set of light transmitting solar cell 12, thereby increasing power generation amount. FIG. 6D shows the set of light transmitting solar cell 12 composed of three light transmitting solar cells and a gap between each of them. This structure also increase power generation amount.

The multiple solar cell panels shown a 3D deployment in the structure of the present invention, thus one of the important thing in the present invention is to distribute sunlight to bigger receiving light area. Although doing this will reduce the light illumination on each solar cell, but increase the total power generation amount. This is different from the concept which focuses light to increase the power generation amount.

In addition, the present invention also provides a method for improving power generation or power generation efficiency of solar cell on unit erected area, comprising a solar cell panel configured in a three-dimensional uneven shape. The uneven shape may be any of three-dimensional geometries, including a sine wave, a square wave, a triangular wave, a sphere, a cone, a column, a prismoid, a polyhedron, a curved body, a barrel, a ring, or any combination thereof. The uneven shape solar cell erect on a fixed erected area can scatter the light received on the solar cell panel to bigger area of solar cell panel, thus increase power generation or power penetration efficiency on unit erected area. That is, increasing the surface area of solar cell on unit erected area to scatter sunlight to the solar cell which has bigger area can increase the power generation amount of solar cell on unit erected area.

The embodiments below exemplarily described the present invention.

### Embodiment 1

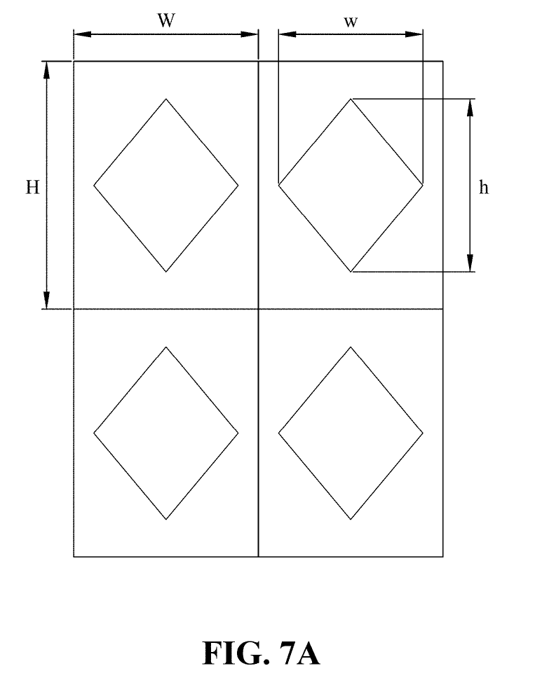

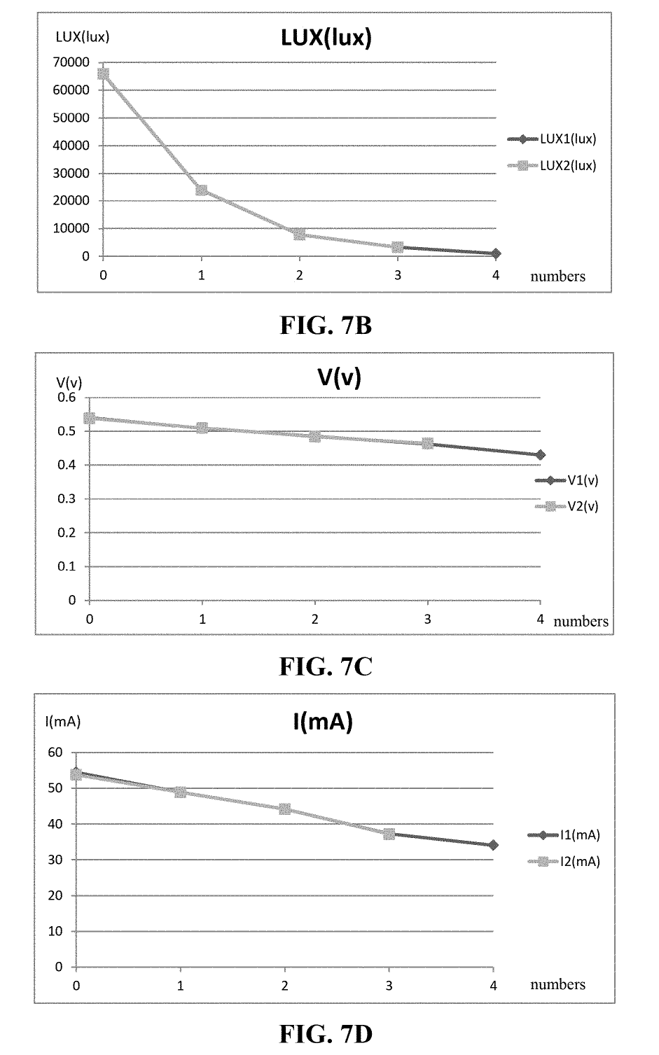

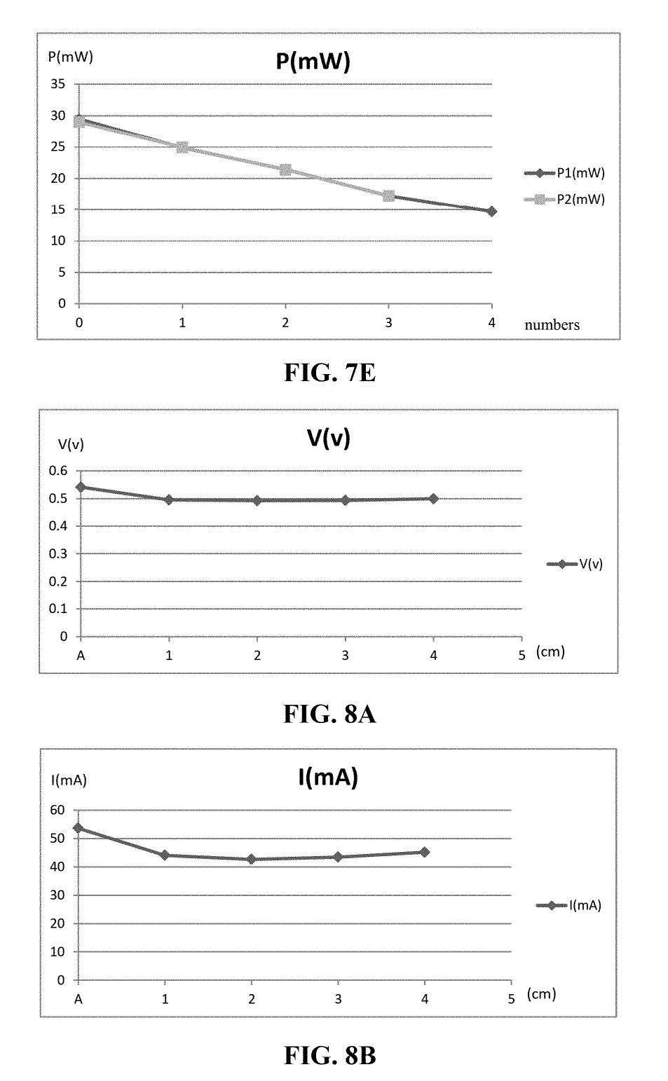

Under an environment of 66000±500 lux, 34° C., we measured the output voltage V, current I and power P of a solar cell penal. Four imitations of solar cell having light transmitting holes are made by dark brown color PolyVinyl Chloride (PVC) pad with rhombus holes (an anti-slip mat, also called screen panel hereafter). The pad is opaque except the holes. The area of rhombus holes occupied 0.2725 times of total area of the pad, thus the transmittance of the pad is 0.2725. FIG. 7A shows the design of the imitation, the size of each unit is 4.3 (H) mm×3.2 (W) mm and the size of rhombus hole is 3 (h) mm×2.5 (w) mm.

We measured the light illumination through 0-4 layer of the imitation, the result showed in FIG. 7B. In the figure, the curve labeled “LUX1” represents the illuminance measured by increase the imitation successively and the curve labeled “LUX2” represents the illuminance measured by decrease the imitation successively. The vertical axis represents the number of the imitation.

We measured the output voltage V, current I and power P of the solar cell covered with 0-4 layer of the imitation, the result showed in FIGS. 7C-7E. In the figures, the curve labeled V1, I1 and P1 measured by increase the imitation successively and the curve labeled V2, I2 and P2 measured by decrease the imitation successively.

FIG. 7B shows the illumination decreasing with the number of the imitations. The illuminances received by the solar cell covered with 1-4 layer of imitation are 0.361, 0.118, 0.05 and 0.0152. The measured value would be higher than theoretical value since at least the diffraction phenomenon. Compare to the theoretical value, the output current and power change are roughly proportional to illuminance changes, but the output voltage change is much gentle. In FIG. 7C, the output voltage changes, but changes much gentle. In FIGS. 7D and 7E, compare to the changes of output current and power, the change of illuminance is relatively gentle. That is, with the reducing of illuminance, the changes of output current and power is not a linear change. Theoretically, the change of output power is according to the change of illuminance. If the change of output current, power and illuminance are linearly proportional, the output current of the solar cell covered with 0-4 imitations should be 54.5 mA, 19.67 mA, 6.431 mA, 2.725 mA, 0.828 mA respectively, the output power of the solar cell covered with 0-4 imitations should be 29.48 mW, 10.642 mW, 3.479 mW, 1.474 mW, 0.448 mW respectively. In this embodiment, for easy calculation, the theoretical value only proportional to the illuminance (that is, the multiplier is 1 while without any imitation). The multiplier of output power of the solar cell covered with 1-4 imitations should be 0.361 (covered with one imitation), 0.118 (covered with two imitations), 0.05 (covered with three imitations) and 0.0152 (covered with four imitations) respectively. The theoretical power is not calculated by multiplying the current and voltage. Theoretically, the change of output voltage decreases with decreased illuminance, the theoretical power calculated by multiplying the current and voltage would be much lower. The measured output current of the solar cell covered with 0-4 imitations is 54.5 mA, 48.9 mA, 44.2 mA, 37.3 mA and 34.1 mA respectively, the measured output voltage of the solar cell covered with 0-4 imitations is 0.541 V, 0.509 V, 0.485 V, 0.462 V and 0.430 V respectively, the measured output power of the solar cell covered with 0-4 imitations is 29.48 mW, 24.89 mW, 21.44 mW, 17.23 mW and 14.66 mW. The output current of the solar cell covered with 1-4 imitations divided by the value without imitation, the ratios are 0.897, 0.811, 0.684 and 0.626 respectively. The output power of the solar cell covered with 1-4 imitations divided by the value without imitation, the ratios are 0.844, 0.727, 0.584 and 0.497 respectively. The illuminance of the solar cell covered with 1-4 imitations divided by the value without imitation, the ratios are 0.361, 0.118, 0.05 and 0.0152 respectively. Among the illuminance, output current and power, the decreasing trend of output current and power is far below the decreasing trend of illuminance.

This result proves that conversion efficiency of solar cell reduces while the light intensity is too high. Thus, under high illumination light, distributing light to other solar cell would increase power generation amount on unit erected area.

We can calculate the effect of each imitation by the result of embodiment 1. Under 66000 lux of light, the output power of single solar cell was 29.48 mW. We covered 1-4 imitations on the solar cell, the output powers of the solar cell are 24.89 mW, 21.44 mW, 17.23 mW and 14.66 mW respectively. Afterwards, we normalized the area of the solar cell to 1 and calculated the total area of the solar cells on the unit erected area. The area of the imitation is 0.7275 and we assume the output power of 1-3 layer solar cell are 24.09×0.7275=18.11 mW, 21.44×0.7275=15.60 mW and 17.23×0.7275=12.53 mW respectively. The 4^{th} layer solar cell (the base solar cell) can employ the solar cell without light transmitting holes and its output power is calculated as 14.66 mW. The output power of each layer differs, while the top layer facing the sun produces the maximum amount of power, and the output power of each layer declines according its order, from top to bottom. However, in a fixed erected area, because it has multiple solar cells to generate the power, the total power is increased. In this embodiment, the area of one solar cell plus 4 imitations equal to 3.18 solar cells panel without light transmitting holes. The total output power is 60.9 mW (18.11 mW+15.60 mW+12.53 mW+14.66 mW=60.9 mW), which is 2.45 times of the output power of single solar cell. Although it seems that we utilize 3.18 solar cells but gain 2.45 times of output power (compared to one solar cell). In fact, we occupy the area of one solar cell and gain 2.45 times of output power. It is useful for generating power on limited area and needing more power. By constructing this construction, we can get more power on smaller light receiving area. If we construct a construction which only employ two solar cell panels (the one with holes is on the top, the one without holes is at the bottom), it has 1.7275 solar cells area in total and the output power is 39.55 mW (1.59 times of single solar cell).

It proved that the multiple layers structure of the set of solar cells comprising solar cells with light transmitting holes could improve total output power on fixed erected area.

### Embodiment 2

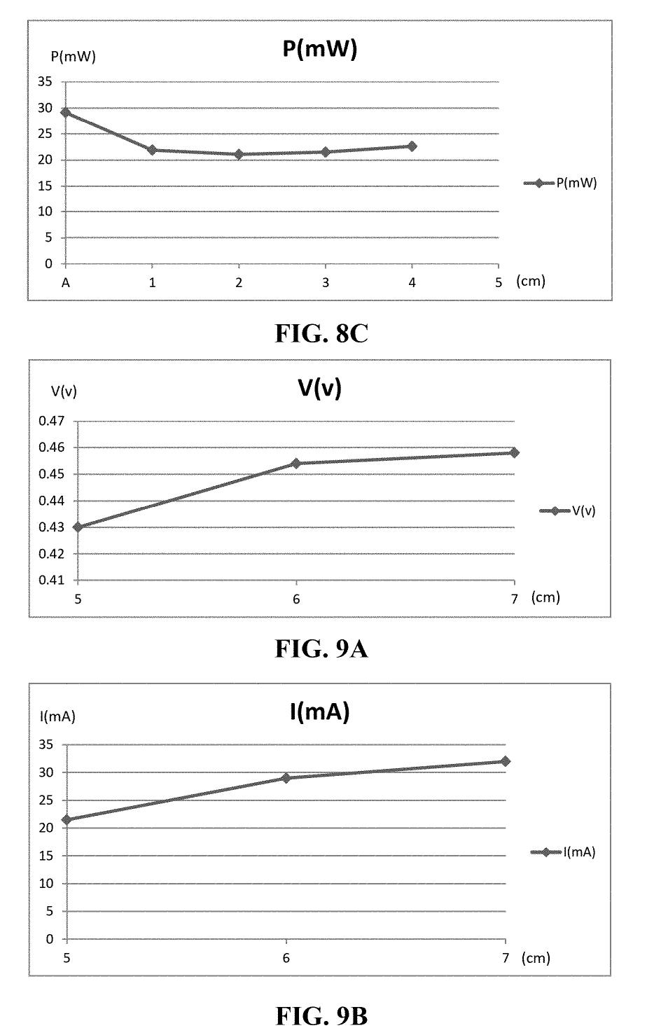

Under 53000±200 lux of light, we measure the output voltage V, current I and power P of the solar cell penal which is the same as in Embodiment 1. Then, we deploy the imitation on the solar cell penal with 1 cm distance and measure the output voltage, current and power. We also measure the output voltage, current and power while the distance is 2, 3 or 4 cm. The result shows in FIGS. 8A-8C. The 1-4 cm at horizontal axis represents the distance of the imitation to the solar cell penal. The “A” at horizontal axis represents the solar cell penal without covered the imitation. By the figures, we found that the output voltage, current and power of the solar cell penal decreased while the imitation is covered on it, but a increasing trend is found at the increasing distance between the imitation and the solar cell penal. It proved that the power generation amount increases with the increasing distance between the imitation (solar cell with light transmitting holes) and the solar cell penal (based solar cell) (3D structure).

### Embodiment 3

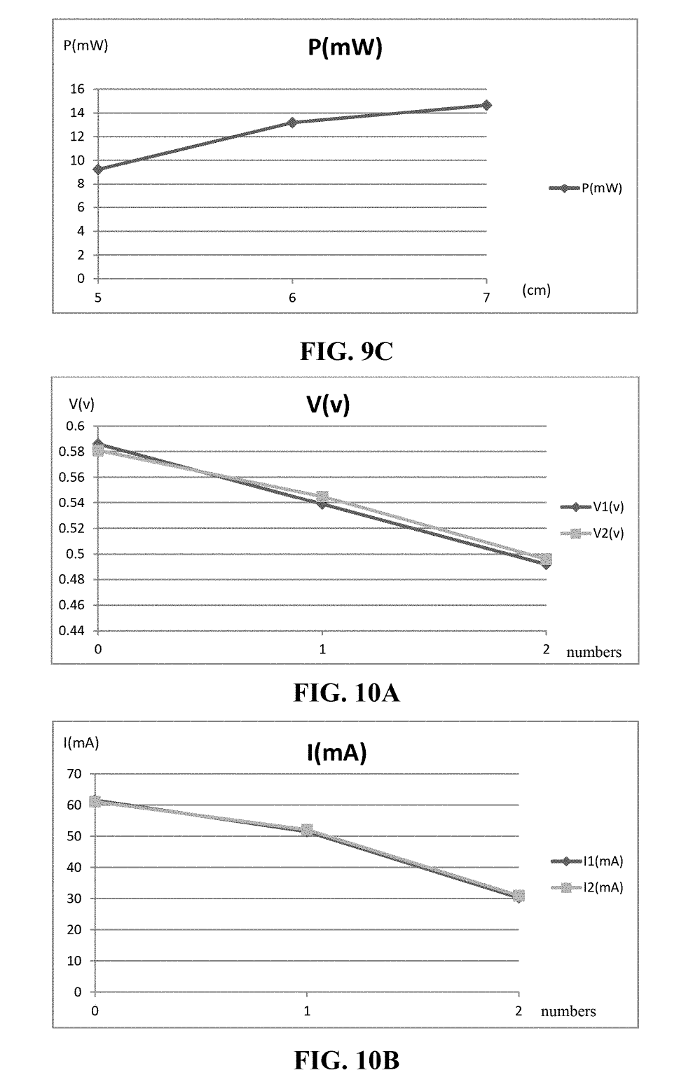

We use the same materials and under the same environment as Embodiment 2. The solar cell covered with two imitations, deploying at a distance of 4 and 5 cm from the solar cell. We measure the output voltage, current and power. We put the imitation from the distance of 5 cm to 6 or 7 cm and measure the output voltage, current and power. The result shows in FIGS. 9A-9C. By comparing the output voltage, current and power values, we found that the output voltage, current and power increase with the distance between the upper imitation and the solar cell and the lower imitation. This embodiment also proves that the 3D structure of multi-layer solar cells comprising the set of light transmitting solar cell with light transmitting holes can improve the power generation amount on fixed erected area.

The same base solar cell and two imitation (to imitate two light transmitting solar cells) to change their distance (one imitation is 4 cm away from the solar cell and the other is 5, 6 or 7 cm) and compare the output power. The output powers of the base solar cell are from 9.245 mW to 14.656 mW, that is, the distance between the upper imitation and the lower imitation or the solar cell can improve the power generation amount of the base solar cell. It is proved that the 3D multi-layer solar cells structure comprising the set of light transmitting solar cell with light transmitting holes can improve the power generation amount on fixed erected area.

### Embodiment 4

Under 66300±500 lux of light, we put the solar cell into a 2000 c.c. beaker and add 1000 c.c. water for the experiment. First, we measure the output voltage, current and power of the solar cell. Then repeat the measure after cover an imitation on it, and repeat the measure after cover another imitation on the imitation (without distance). The experimental structure shows in FIG. 6A. The result shows in FIGS. 10A-10C. In the figures, the “0” in the horizontal axis represents no imitation covered on the solar cell; the “1” and “2” represent 1 and 2 imitation(s) covered in the solar cell. The “V1”, “I1” and “P1” represent the change of voltage, current and power while the imitation number increases; the “V2”, “I2” and “P2” represent the change of voltage, current and power while the imitation number decreases. The result of sank in water is similar to the result of in air. Although the decrease amount of voltage, current and power are more than the result of in air, the decrease amount still much smaller than the decrease of light illuminance (based on the illuminance measured in air). This embodiment proves that the 3D structure of multi-layer solar cells comprising the set of light transmitting solar cell in the liquid also can improve the power generation amount on fixed erected area.

### Embodiment 5

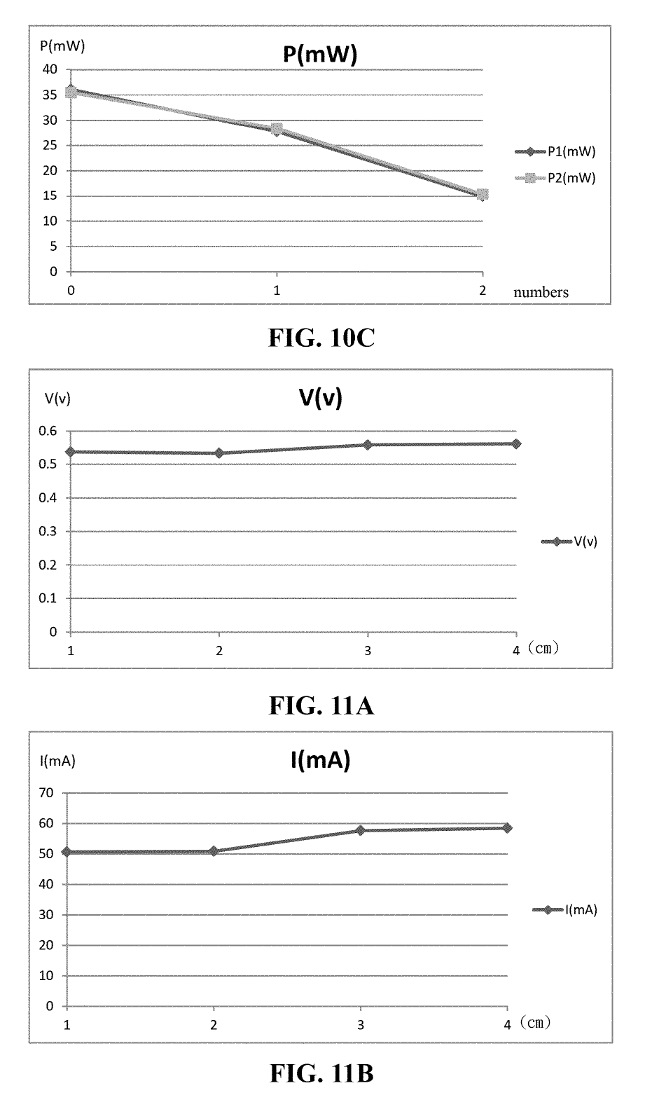

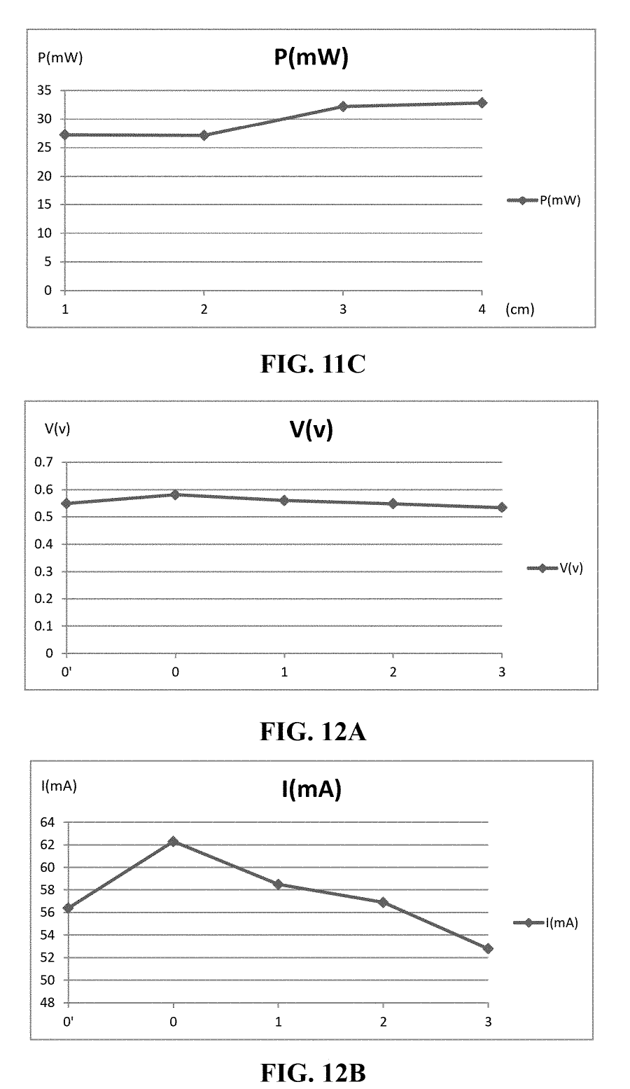

Under the same light illuminance with embodiment 4, we put the solar cell into a 2000 c.c. beaker and add 1000 c.c. water for the experiment. First, we put an imitation on the solar cell with a distance of 1, 2, 3 or 4 cm and measure the output voltage, current and power of the solar cell. The experimental structure shows in FIG. 6B and the result shows in FIGS. 11A-11C. Based on the result, we found the output voltage, current and power increase with the distance between the solar cell and the imitation. The increasing trend is similar to the result in the air. It is also proved that the 3D structure can improve power generation amount.

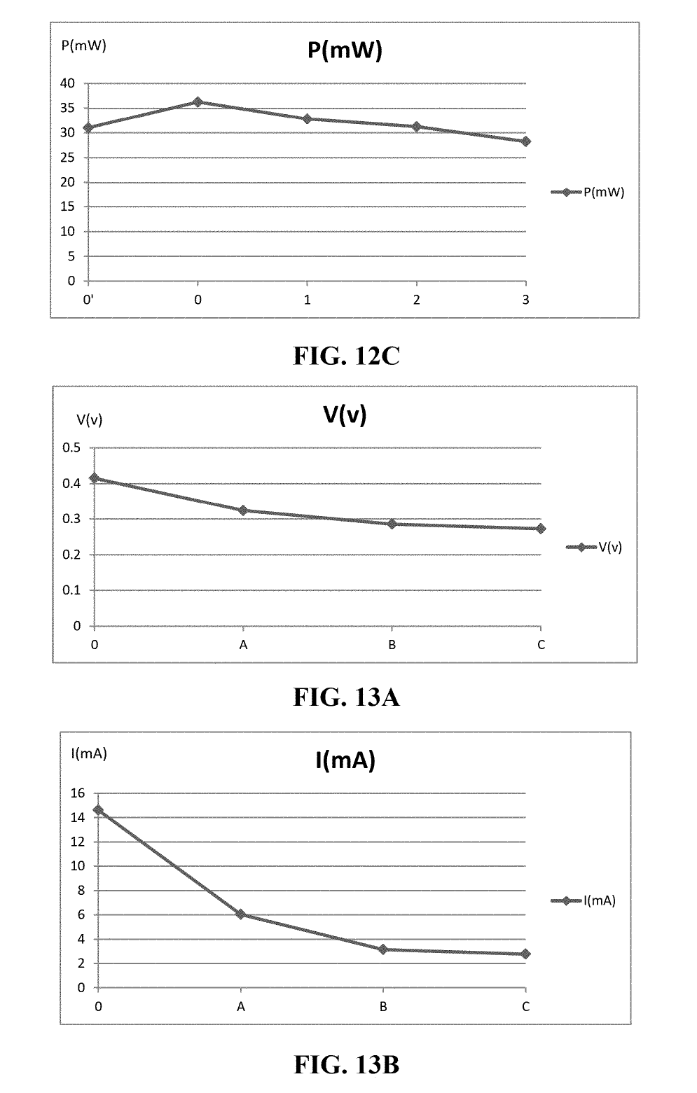

We put an imitation on the solar cell penal with a distance of 4 cm and put another imitation on the solar cell penal with a distance of 6 cm, as shown in FIG. 6C. We measure the output voltage, current and power of the solar cell penal. Then, we put a third imitation on the solar cell penal with a distance of 7 cm, as shown in FIG. 6D, and measure the output voltage, current and power of the solar cell penal. The result is shown in FIGS. 12A-12C. In the figures, the “0′” in the horizontal axis represents the solar cell is measured in the air; “0” represents the solar cell is measured in the water; “1” represents one imitation deploying on the solar cell penal with a distance of 4 cm; “2” represents the second imitation further deploying on the solar cell penal with a distance of 6 cm; “3” represents the third imitation further deploying on the solar cell penal with a distance of 7 cm. Based on the imitation transmits the light in a ratio of 0.2725, the total power generation amount would be 36.098×(1−0.2725)+32.819×(1−0.2725)+30.744×(1−0.2725)+28.248=100.751 mW, which is more than the single solar cell penal in water (36.259 mW).

Please refer to FIG. 12C, the power generation amount of the solar cell in the air is 31.02 mW; the power generation amount of the solar cell in water is 36.098 mW. We assume a structure deploying a base solar cell (with no hole) and a light transmitting solar cell (the area of light transmitting holes occupy the total area in a ratio of 0.2725) with a distance of 4 cm, the total area of solar cell penal is 1.7275 times of single solar cell penal and total power generation amount is 59.080 mW. The output power of this structure is 1.637 times of the output power of single solar cell penal in water (36.098 mW), the ratio is similar to the area ratio, 1.7275. The output power of this structure is 1.905 times of the output power of single solar cell penal without water (31.02 mW), the ratio is greater than the area ratio, 1.7275. That is, we use the 1.7275 times solar cell penal and get 1.905 times of output power. The area of the structure of a base solar cell and three light transmitting solar cells (shown as in FIG. 12C) is 3.183 (the area of single solar cell penal is 1) and the output power is 100.751 mW (2.791 times of single solar cell penal in water, 36.098 mW). The output power is 3.248 times of single solar cell penal without water (31.02 mW). That is, the output power increases to 3 times on the fixed sunlight illumination area. It is useful for the small device such as watch and cell phone or vehicle, airplane, boat, spacecraft and satellite. The solar cell is not limit to any solar cell, comprising a solar cell made of Si, GaAs, organic material or inorganic material; or such as a thin film solar cell or thick film solar cell. The light source and environment is also not limited, such as fluorescent lamp and under water.

Base on the results above, putting the solar cell into the water can improve the power generation amount. Covering the imitation (imitating the solar cell with light transmitting holes) on the solar cell decreased the output voltage, current and power, but it didn't decrease too much. Thus, the 3D structure of solar cell can improve the power generation amount.

### Embodiment 6

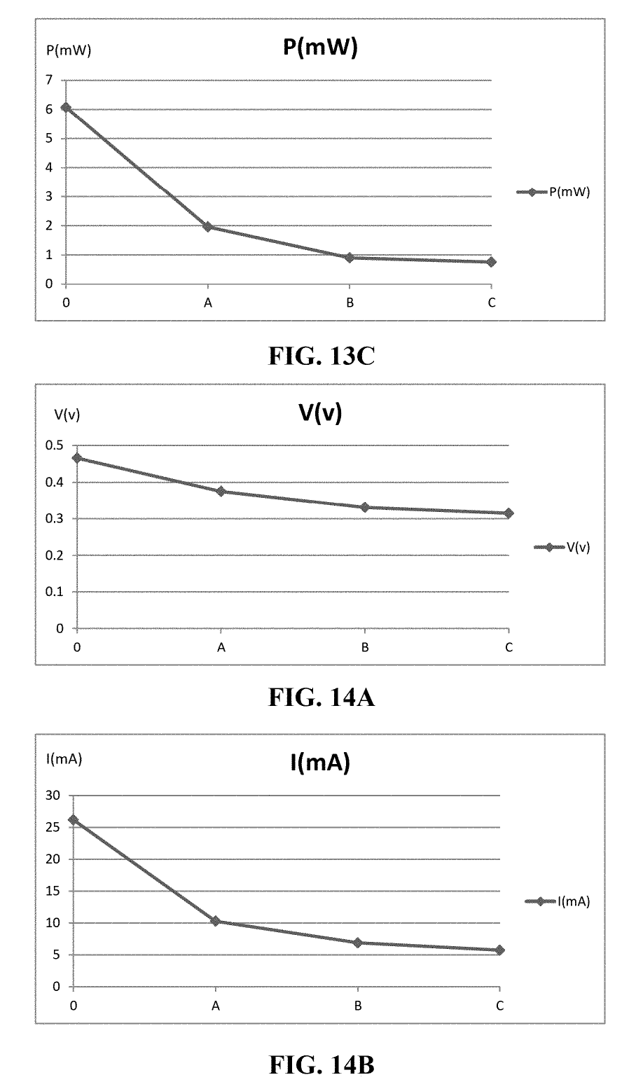

Under 4600±200 lux, 22° C., we measure output voltage V, current I and power P of the solar cell, the results show in FIGS. 13A-13C (labeled “0” on the horizontal axis). We put an imitation (same as in embodiment 1; represented by imitation 1 below) on the solar cell with a distance of 4 cm and measure its output voltage, current and power, the results also show in FIGS. 13A-13C (labeled “A”). We further put an imitation (imitation 2) on the solar cell with a distance of 6 cm and measure its output voltage, current and power, the results also show in FIGS. 13A-13C (labeled “B”). We further put an imitation (imitation 3) on the solar cell with a distance of 9 cm and measure its output voltage, current and power, the results also show in FIGS. 13A-13C (labeled “C”). Among the results of 0-3 imitations, total power generation amount is from 6.071 mW to 6.374 mW, 6.741 mW and 7.252 mW. The calculation method is 6.071 mW×(1−0.2725)+1.957 mW=6.374 mW (with 1 imitation).

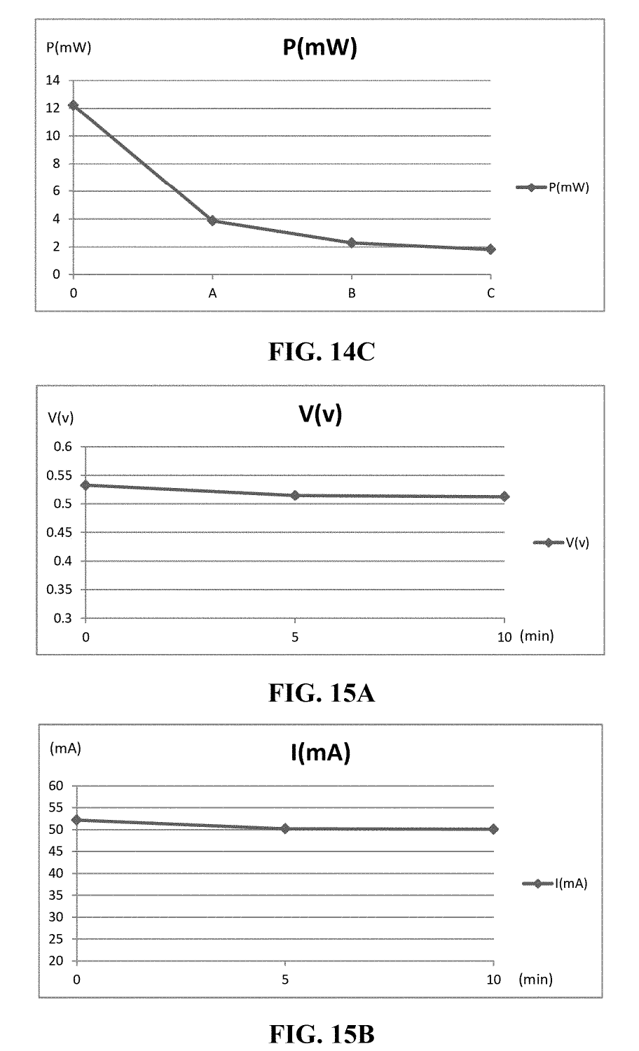

We repeat the experiment under 8600±200 lux, 22° C., the results show in FIGS. 14A-14C. The output power of the solar cell penal covered with 0-3 imitations are from 12.209 mW to 12.745 mW, 13.976 mW and 15.065 mW. Thus, we found that adding the imitations can still improve the power generation amount under weak sunlight, but the increment is less. That is, combining multiple solar cells can still improve the power generation amount under weak sunlight, but the increment is less.

### Embodiment 7

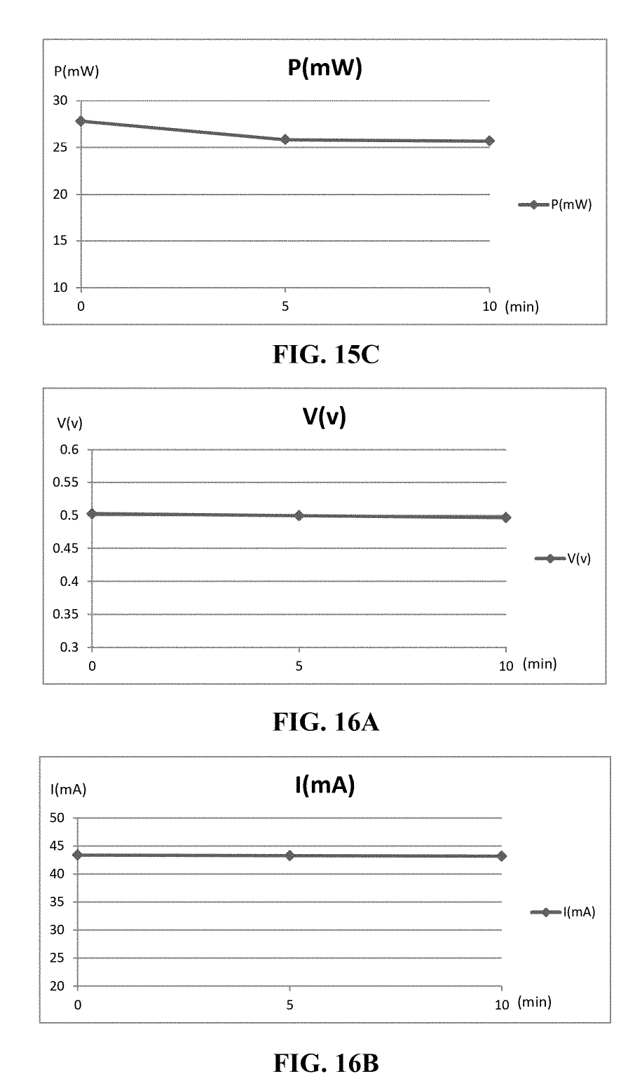

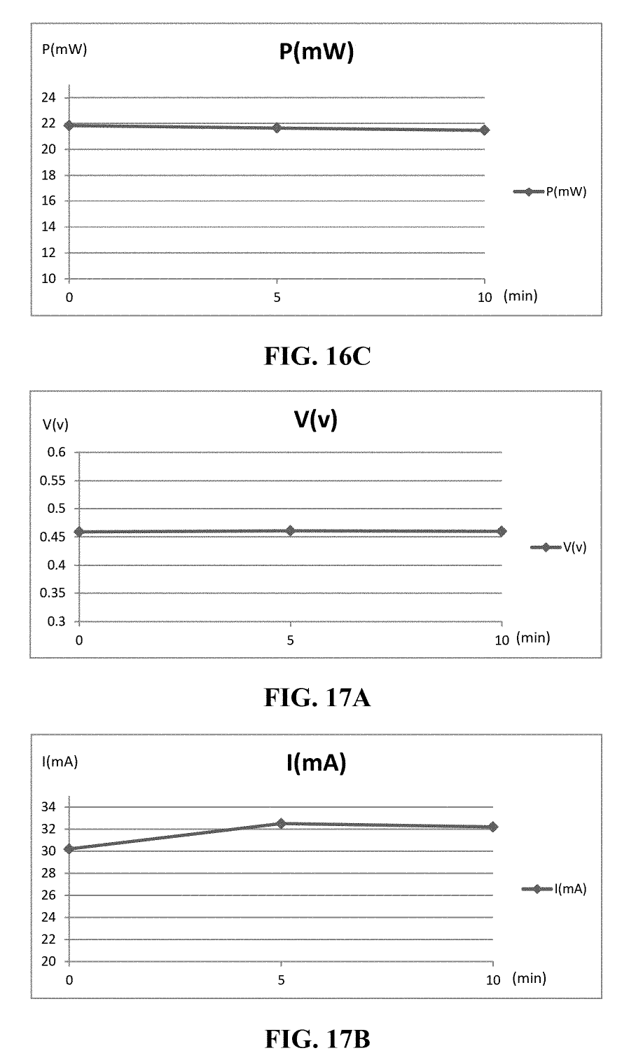

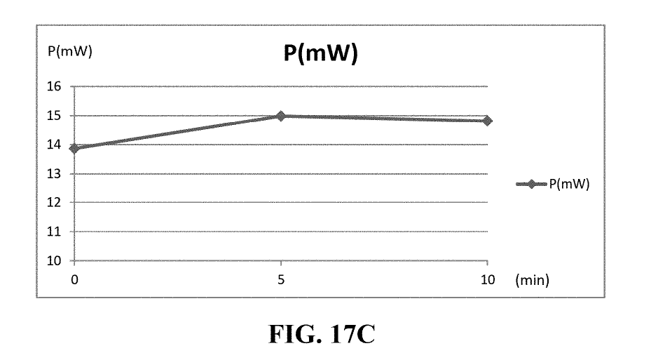

Under 59000±300 lux, 31° C., we measure the output voltage, current and power of the solar cell in different sunlight illuminating time. FIGS. 15A-15C show the output voltage, current and power of the solar cell at the sun illuminating time of 0, 5 and 10 mins. Based on the figures, the surface temperature of the solar cell raised with the sun illuminating time, thus the output voltage, current and power decreased. FIGS. 16A-16C show the output voltage, current and power of the solar cell covered one imitation (with no distance) at the sun illuminating time of 0, 5 and 10 mins. Based on the figures, with the sun illuminating time increasing, the changes of the output voltage, current and power are insignificant, showing that the effect of temperature is insignificant. FIGS. 17A-17C show the output voltage, current and power of the solar cell covered two imitations (with no distance) at the sun illuminating time of 0, 5 and 10 mins. Based on the figures, with the sun illuminating time increasing, the changes of the output voltage, current and power are insignificant (the slightly raised value should be caused by sunlight illumination change). In conclusion, the solar cell penal covering two or three imitations can reduce the effect of raised temperature caused by sun illumination. If we generate power by multi-layer solar cells, the power generation effecting by high temperature would be reduced. It is one of the benefits of using multi-layer solar cells to generate power.

### Embodiment 8

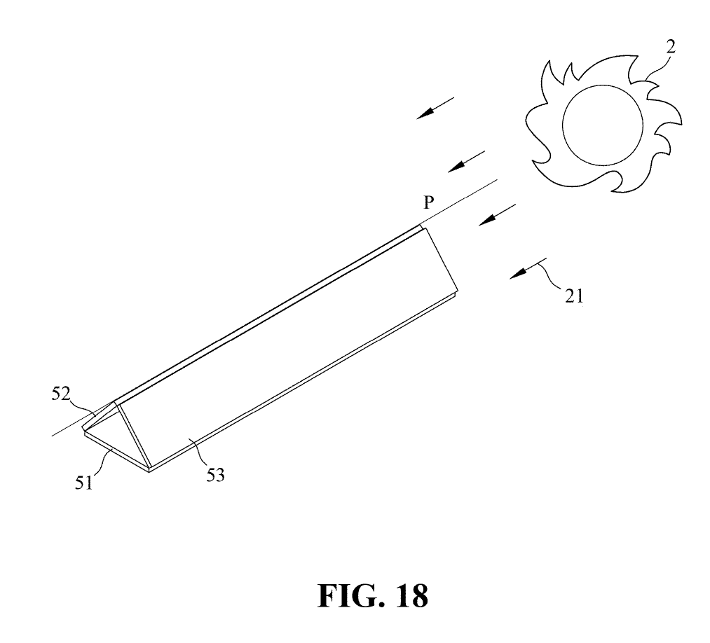

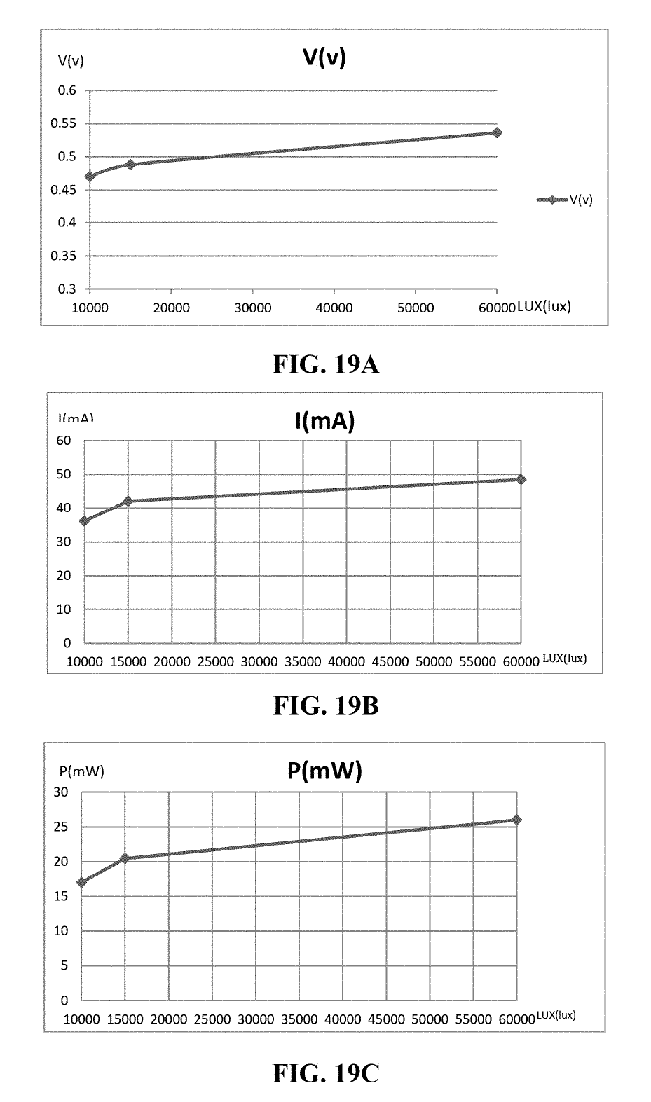

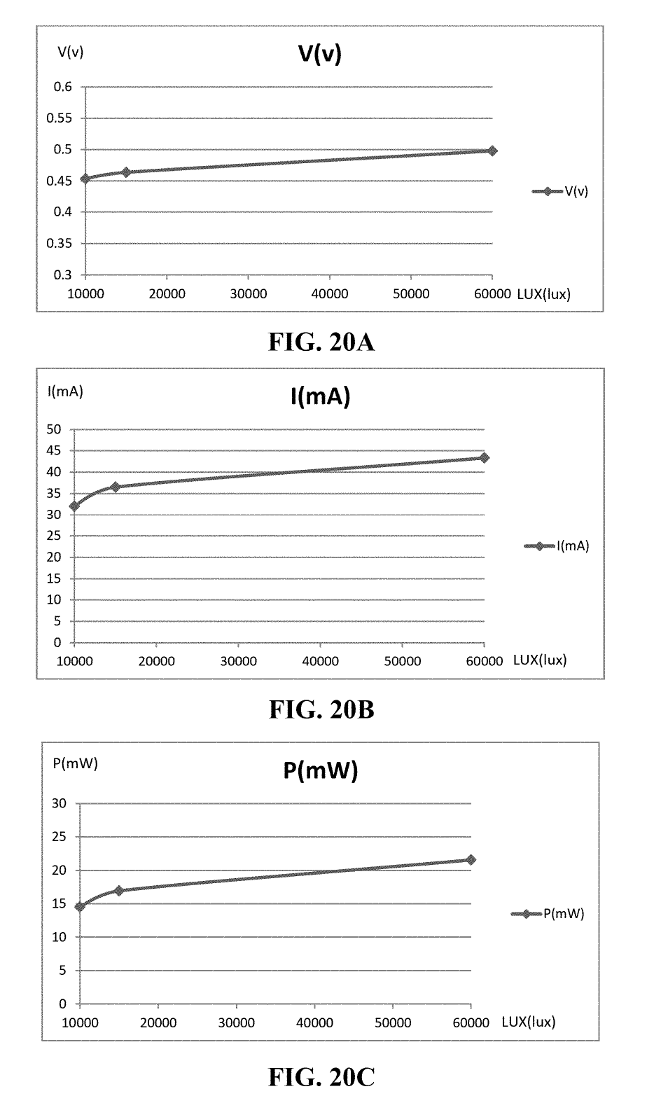

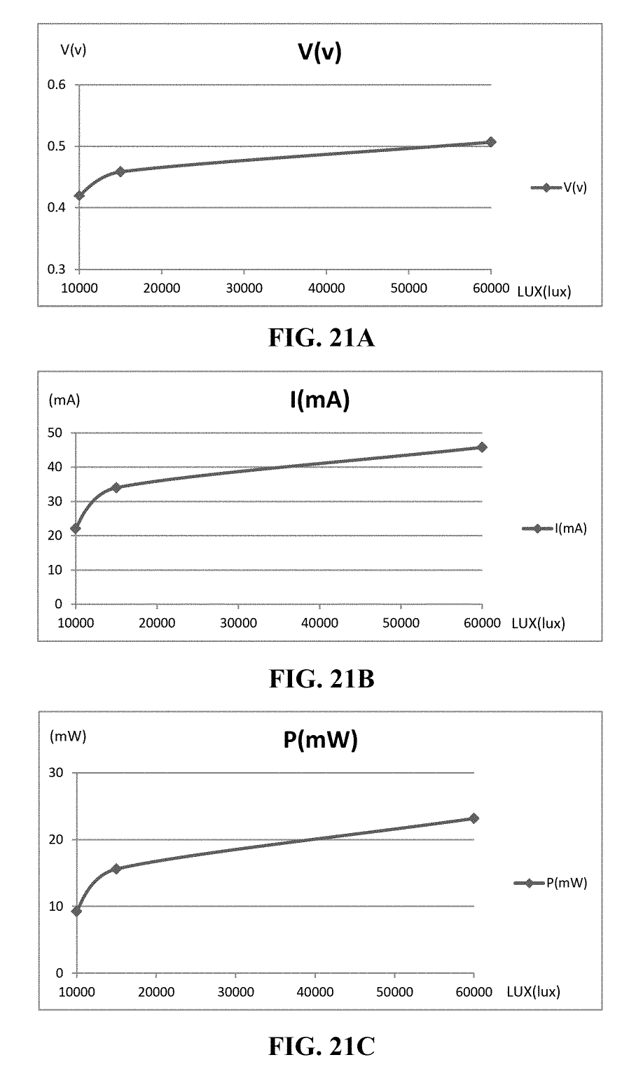

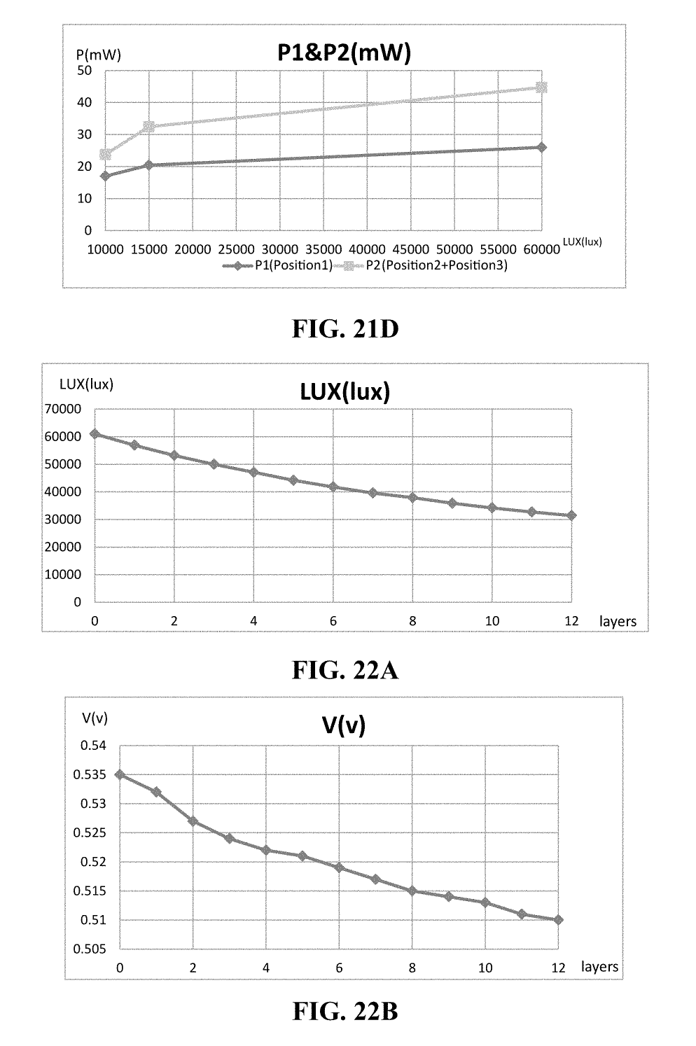

To determine the power generation amount of solar cell utilizing light scattered method on a fixed erected area, we employ uneven shape solar cell to generate power under 32° C. (the exemplary structure shows in FIG. 18). For more accurate, we use a solar cell (5 cm×4 cm) for every measurement in this embodiment. The solar cell is deployed normal (position 1, solar cell 51), left (position 2, solar cell 52) and right (position 3, solar cell 53) position, and we measure the output voltage, current and power. The left and right solar cell clamp with 60°, thus the project area become is half of the original. The angle is adjustable. The axial of the 3D structure (ridgeline P in FIG. 18) aligns the sun or the directions of sun movement, thus the position 2, 3 of solar cells receive uniform light. The direction is not limited, is adjustable. FIGS. 19A-19C show the output voltage, current and power while deploying the solar cell at position 1 under 10000 lux, 15000 lux or 60000 lux. FIGS. 20A-20C show the output voltage, current and power while deploying the solar cell at position 2 under 10000 lux, 15000 lux or 60000 lux. FIGS. 21A-21C show the output voltage, current and power while deploying the solar cell at position 3 under 10000 lux, 15000 lux or 60000 lux.

FIG. 21D shows the output voltage, current and power while deploying the solar cell 51 at position 1 under 10000 lux, 15000 lux or 60000 lux and the total of output voltage, current and power while deploying the solar cells 52 and 53 at position 2 and 3 under 10000 lux, 15000 lux or 60000 lux. By the figures, the output power of 3D structure (position 2 plus position 3) is 1.4-1.7 times of the solar cell at position 1. The 3D structure and the solar cell at position 1 occupy the same erected area. Although the 3D structure takes 2 times of cost, this uneven shape 3D structure provides a high solar cell power generation method in limited light receiving area.

We repeat this experiment; align ridgeline to the sun (as shown in FIG. 18) and measure the output voltage, current and power under outdoor 65000 lux, 31° C. The structure is as FIG. 18. The output voltage, current and power of solar cell penal 52 with an inclination of 60 degrees is 0.484V, 46.4 mA and 22.46 mW. The output voltage, current and power of solar cell penal 53 with an inclination of 60 degrees is 0.511V, 49.4 mA and 25.24 mW. The output voltage, current and power of solar cell penal 51 with no inclination angle is 0.53V, 52.5 mA and 27.83 mW. The total output power of the solar cells at position 2 and position 3 is 47.70 mW, which is significantly more than 27.83 mW (the output power of solar cell at position 1). Although the structure employs two solar cell panels, it can generate more power on a fixed sun illumination area.

By described above, the uneven shape 3D structure can improve power generation amount on fixed erected area. It is useful for the applications which have limited area.

### Embodiment 9

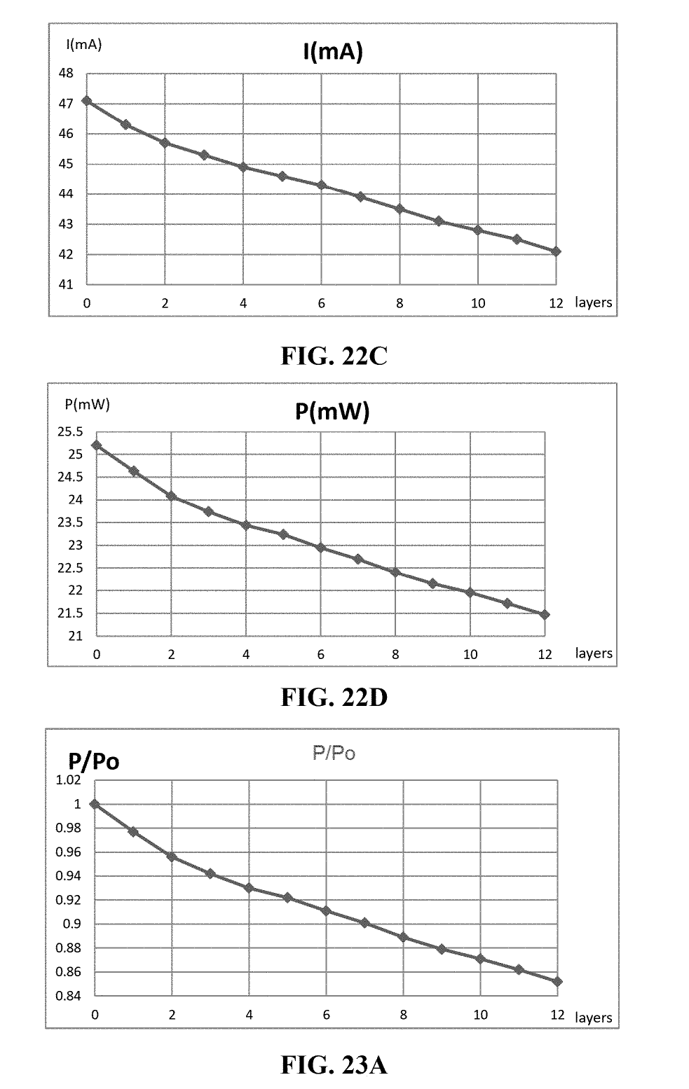

We use the multiple solar cells (the structure shows in FIG. 3B) to generate power under 60500±500 lux, 19° C. The concept is that every solar cell transmits partial light to the solar cell under itself and thereby distributing the light to every solar cell on a fixed solar cell erected area (fixed sun light illumination area) and improving the total power generation amount. We employ 12 solar cell panels to form a 3D structure for exemplary, every solar cell except for the base solar cell panel must transmit partial sun light. For the solar cell panel that can transmit partial sun light, it can be a thin film solar cell or a solar cell made by MEMS technique. In this embodiment, we use glass slide having 0.950 of transmittance to imitating a solar cell having 0.950 of transmittance. First, we measure the output voltage, current and power of the solar cell panel covered with no glass slide. Then, we measure the output voltage, current and power of the solar cell panel covered with one glass slide having 0.950 of transmittance. Then, we measure the output voltage, current and power of the solar cell panel covered with two glass slides having 0.950 of transmittance. We measure the output voltage, current and power of the solar cell panel while adding each glass slide until the solar cell covered with 12 glass slides. The result (illumination, output voltage, current and power) shows in FIGS. 22A-22D.

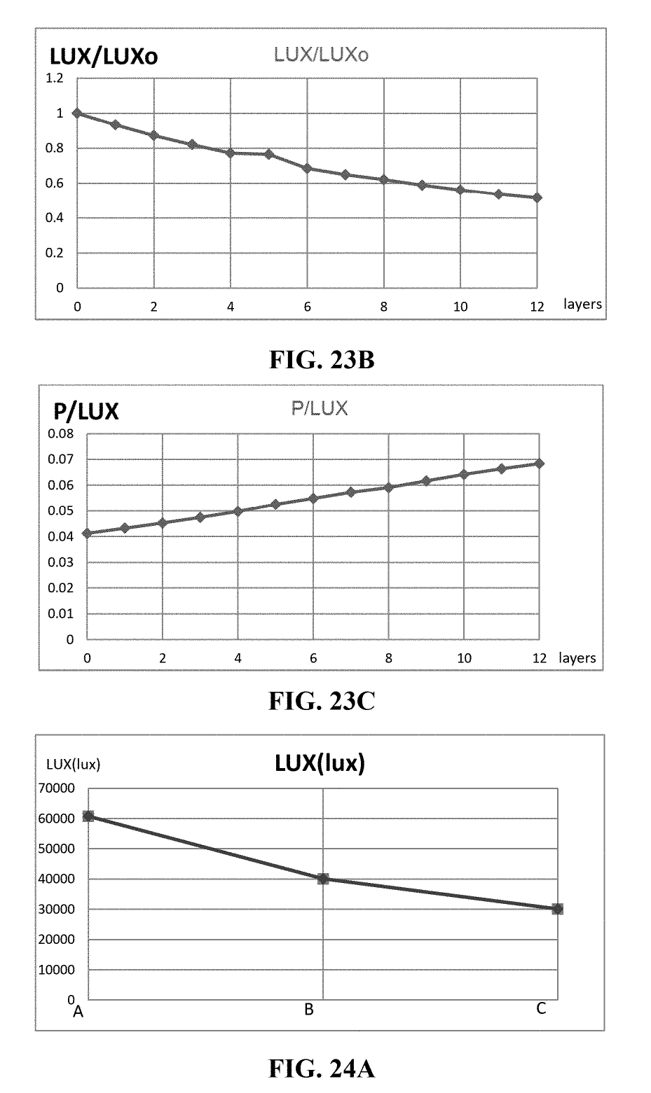

The ratios of P/P₀, LUX/LUX₀ and P/LUX show in FIGS. 23A-23C. In the figures, “LUX” represents the illuminations after covered 1-12 glass slides; “LUX₀” represents the illuminations covered without glass slide (61000 lux); “P” represents the output power after covered 1-12 glass slides; “Po” represents the output power covered without glass slide (25.199 mW). In FIGS. 22A-22D, we obtained that the output voltage, current and power decreased more intense than the illumination reduction. In FIGS. 23A and 23B, we obtained that the P/Po ratio was much greater than LUX/LUX₀ ratio while each glass slide added. In FIG. 23C, we obtained that the output power-illumination ratio increased with glass slide number. It proved that output power reduction is lower than illumination reduction, and proved that the total power generation amount of the structure of multiple solar cell panels is greater than single solar cell panel. Thus, this proved the 3D structure including the set of light transmitting solar cell with light transmitting holes could improve the power generation amount on fixed erected area. Although the structure takes more cost in solar cell, it still provides a method for improving the power generation amount of solar cell on limited light receiving area.

### Embodiment 10

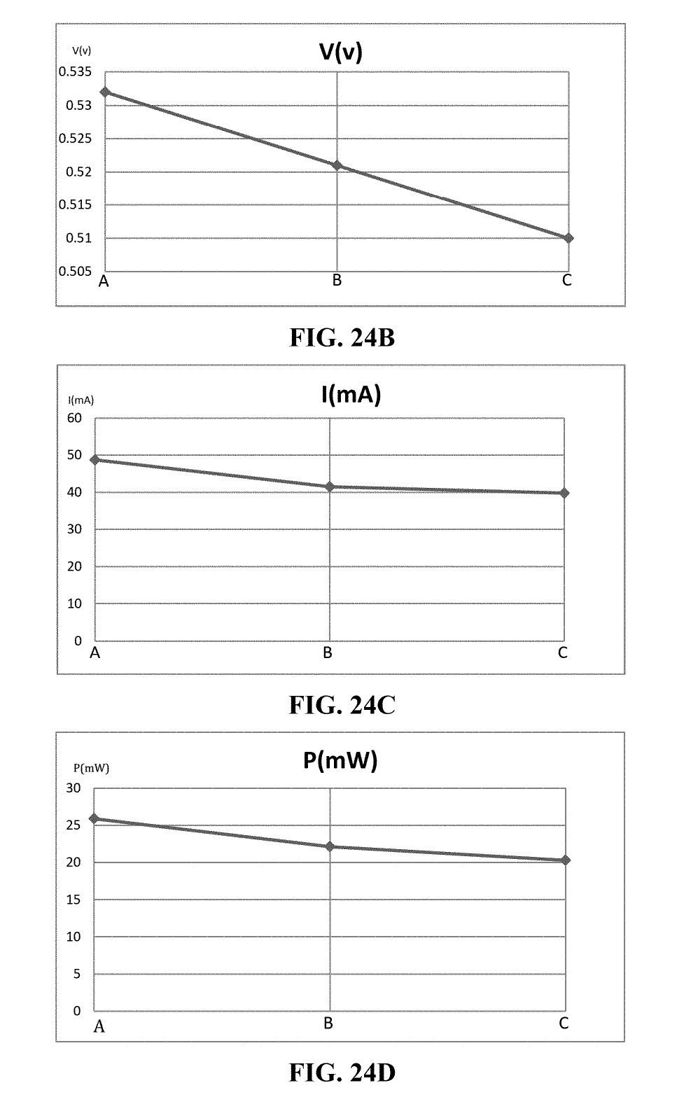

Under 19° C., 60500±500 lux of light, we construct a 3D constructure including multiple solar cell panels to generate power (the structure shows in FIG. 3B). In this structure, each solar cell must transmit partial sun light. The partial transmitting light solar cell can be thin film solar cell or a solar cell made by MEMS technique. The difference between this embodiment and previous embodiment (embodiment 9) is similar to embodiment 5, the second layer solar cell panel (imitated with glass slides, transmittance is 0.657) has a distance of 4 cm from the first solar cell panel; the third layer solar cell panel (imitated with glass slides, transmittance is 0.751) has a distance of 6 cm from the first solar cell panel and has a distance of 2 cm from the second layer solar cell panel. Every layer solar cell is composed of 6 glass slides to reduce light transmittance. FIGS. 24A-24D show the illuminance, output voltage, current and power of three circumstances: the label “A” represents adding no glass slide; the label “B” represents the solar cell covered with six glass slides and has a distance of 4 cm from the solar cell panel, to imitate the light is partially transmitting upper solar cell panel and reach the lower solar cell penal; the label “C” represents the solar cell covered with six glass slides (transmittance is 0.657, the second layer) and has a distance of 4 cm from the solar cell panel (the first layer) and further covered with six glass slides (transmittance is 0.751, the third layer) and has a distance of 6 cm from the solar cell panel (the first layer) and has a distance of 2 cm from the solar cell panel (the second layer), and measure the illuminance, output voltage, current and power of the first layer solar cell.

FIG. 24B shows the output voltages of three circumstances: the label “A” in horizontal axis represents adding no glass slide; the label “B” represents the solar cell covered with six glass slides and has a distance of 4 cm from the solar cell panel, to imitate the light is partially transmitting upper solar cell panel and reach the lower solar cell penal; the label “C” represents the solar cell covered with six glass slides (the second layer) having a distance of 4 cm from the lower solar cell panel (the first layer) and further covered with six glass slides (the third layer) having a distance of 6 cm from the solar cell panel (the first layer) and having a distance of 2 cm from the solar cell panel (the second layer).

FIG. 24C shows the output currents of three circumstances: the label “A” in horizontal axis represents adding no glass slide; the label “B” represents the solar cell covered with six glass slides and has a distance of 4 cm from the solar cell panel, to imitate the light is partially transmitting upper solar cell panel and reach the lower solar cell penal; the label “C” represents the solar cell covered with six glass slides (the second layer) having a distance of 4 cm from the lower solar cell panel (the first layer) and further covered with six glass slides (the third layer) having a distance of 6 cm from the solar cell panel (the first layer) and having a distance of 2 cm from the solar cell panel (the second layer).

FIG. 24D shows the output power of three circumstances: the label “A” in horizontal axis represents adding no glass slide, the output power is 25.2 mW; the label “B” represents the solar cell covered with six glass slides and has a distance of 4 cm from the solar cell panel, to imitate the light is partially transmitting upper solar cell panel and reach the lower solar cell penal, the output power is 22.14 mW; the label “C” represents the solar cell covered with six glass slides (the second layer) having a distance of 4 cm from the lower solar cell panel (the first layer) and further covered with six glass slides (the third layer) having a distance of 6 cm from the solar cell panel (the first layer) and having a distance of 2 cm from the solar cell panel (the second layer), the output power is 20.30 mW.

We assume the output power of the second and third layer solar cell calculated by 1-transmittance. The calculated output power is lower than actual circumstance, because the power-generating region of a solar cell is in depletion region of p-n junction. The depletion region usually is very thin, so most of sun illumination is invalid. The transmittance of the third solar cell is 0.657. We assume the effective power generation is 1−0.657=0.343 (conservative assessment, generally higher than this value). The output power of the third solar cell is 25.2 mW×(1−0.657)=8.644 mW. The output power of the second solar cell is 22.14×(1−0.751)=5.513 mW. The output power of the first solar cell is 20.3 mW. The total output power of three layers is 34.46 mW, which is significantly greater than the output power of single solar cell (25.20 mW). Although the structure takes more solar cells, it still provides greater total power generation amount on a fixed solar cell erected area.

FIGS. 24A-24D show the illumination, output voltage, current and power of the solar cell with adding one upper layer (six glass slides; imitating partial transmitting solar cell) with a distance of 4 cm. Compared to the solar cell without adding the glass slides, the ratio of illumination, output voltage, current and power are 0.660, 0.979, 0.873 and 0.855, respectively. Thus, compared to the solar cell without adding the glass slides, the output power reduction of the solar cell with glass slides is significantly lower than the illumination reduction. In FIGS. 24A-24D, the label “C” in the horizontal axis represents two layers of glass slides (six glass slides for each layer). Compared with the solar cell without adding glass slide, the ratios of illumination, output voltage, current and power are 0.495, 0.959, 0.817 and 0.783, respectively. Thus, compared to the solar cell without adding the glass slides, the output power reduction of the solar cell with glass slides is significantly lower than the illuminance reduction (because 0.783>>0.495). The result proved that the 3D structure improve the power generation amount on fixed light receiving area. Although the structure takes more cost in solar cell, it still provides a method for improving the power generation amount of solar cell on limited light receiving area.

Moreover, we construct a same structure set forth, put it into a 2000 c.c. beaker containing 1000 c.c. water and measure the output voltage, current and power under 65500±500 lux, 22° C. The transmittances of second and third layer are 0.657 and 0.751 respectively. The results of Embodiment 11 are used to estimate the base solar cell (the first layer) which is covered with 12 glasses, the output power of the first layer is 31.27 mW; the second layer of solar cell which is covered with 6 glasses, the output power of the second layer is 32.18 mW; the third layer of solar cell without any glass, the output power of the third layer is 32.92 mW. In the water environment of this example, the third layer of solar cell has a transmittance of 0.751, and the second layer of solar cell has a transmittance of 0.657. We assume the output power of the second layer is 32.18×(1−0.657)=11.038 mW; the output power of the third layer is 32.92×(1−0.751)=8.197 mW. The measured output power of the first layer is 31.27 mW. The total output power is 50.505 mW, which is greater than the output power of single solar cell, 32.92 mW. Because of the structure in water has greater power generation amount, the output power is two times greater than the output power of single solar cell without water (25.2 mW). This is a conservative estimate.

### Embodiment 11

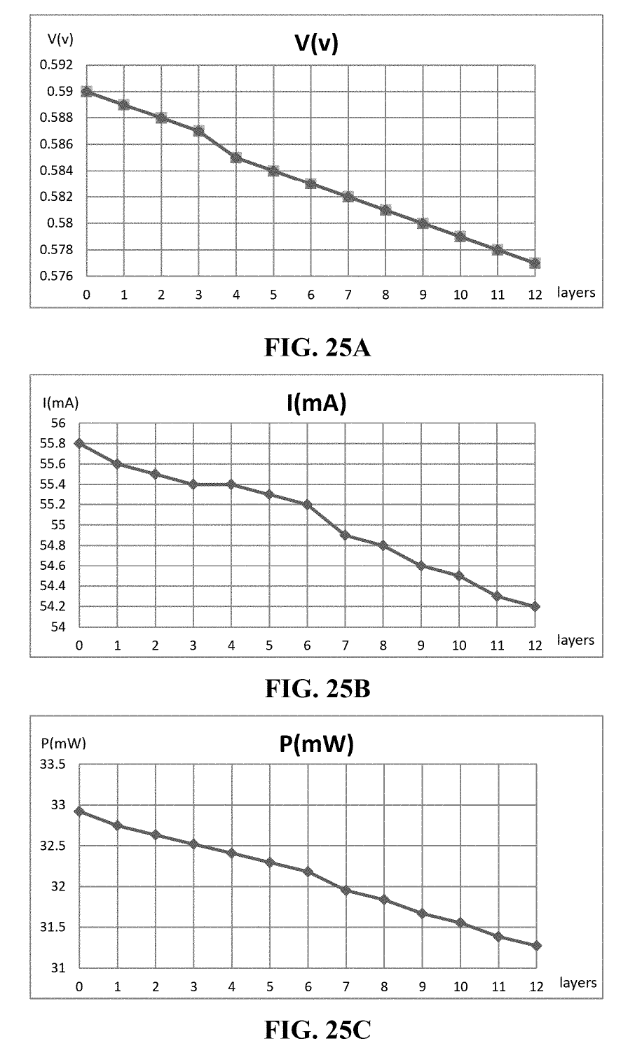

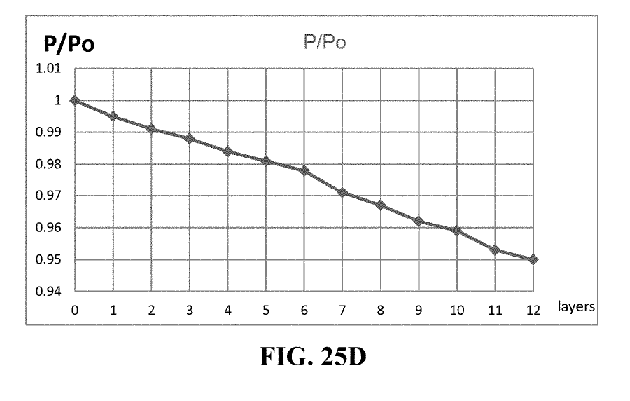

Under 65500±500 lux, 22° C., we put the structure shown in FIG. 6A into a 2000 c.c. beaker containing 1000 c.c. water (FIG. 6A) to generate power. Similar to embodiment 9, each solar cell transmits partial sun light. The partial transmitting light solar cell can be thin film solar cell or a solar cell made by MEMS technique. This embodiment use glass with 0.950 of transmittance to imitate a solar cell with 0.950 of transmittance. The transmittance of each layer is 0.950. The first layer is a solar cell without adding glass. We measure the output voltage, current and power of the solar cell covered without glass. We put a glass with transmittance of 0.950 (to imitate the second layer of solar cell with transmittance of 0.950) on the solar cell and measure the output voltage, current and power. We further put a glass with transmittance of 0.950 (to imitate the third layer of solar cell with transmittance of 0.950) on the solar cell and the second layer of solar cell imitation, and measure the output voltage, current and power. We measure the output voltage, current and power of the solar cell panel while adding each glass slide until the solar cell covered with 12 glasses. The results (illuminance, output voltage, current and power and P/Po) show in FIGS. 25A-25C (P is the output power of the solar cell adding glasses and Po is the output power of the solar cell without adding glass). The P/Po reduction is lower than the P/Po reduction in the embodiment 9.

The results shown in FIGS. 25A-25C is similar to the results in embodiment 9, proving that the power generation amount of the structure including multiple solar cell is greater than single solar cell. Thus, the 3D structure can improve the total power generation amount on a fixed light receiving area. Although the structure takes more cost in solar cell, it still provides a method for improving the power generation amount of solar cell on limited light receiving area. Moreover, FIG. 25D shows the ratios P/Po. The structure in this embodiment is similar to the embodiment 9, the difference between this embodiment and the embodiment 9 is with/without water. In comparison with the lux of embodiment 9 and FIGS. 22A-22D and 23A, based on the structure comprising multiple solar cells, the reduction of P is still much smaller than the reduction of lux.

### Embodiment 12

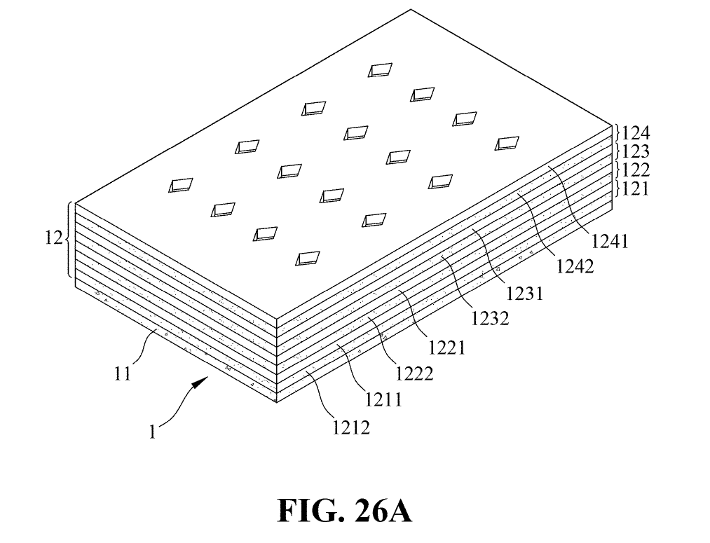

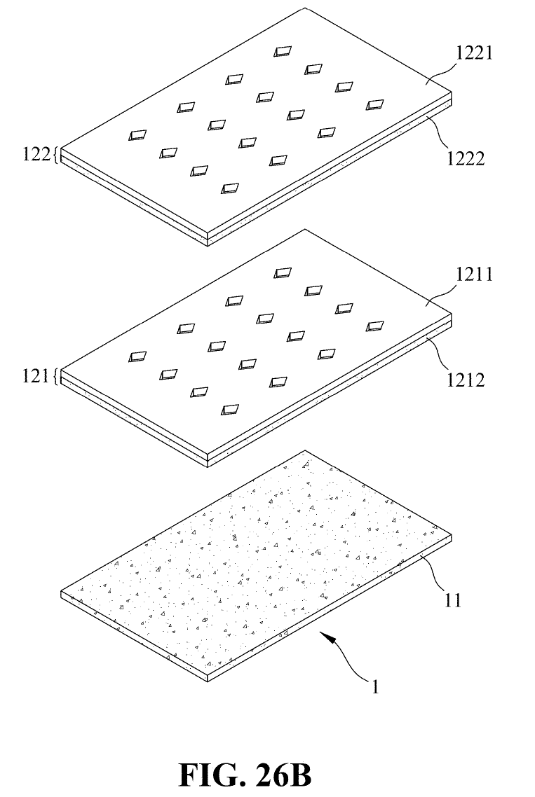

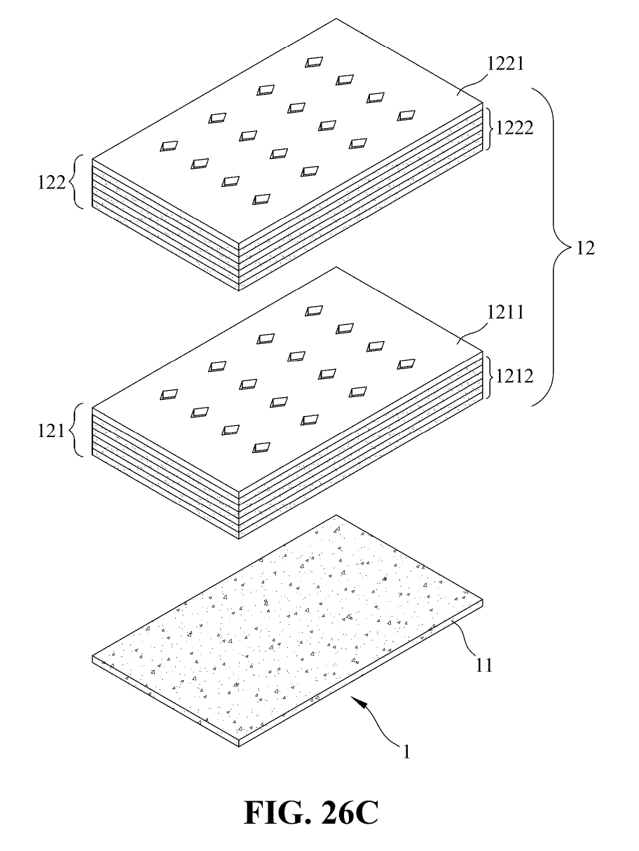

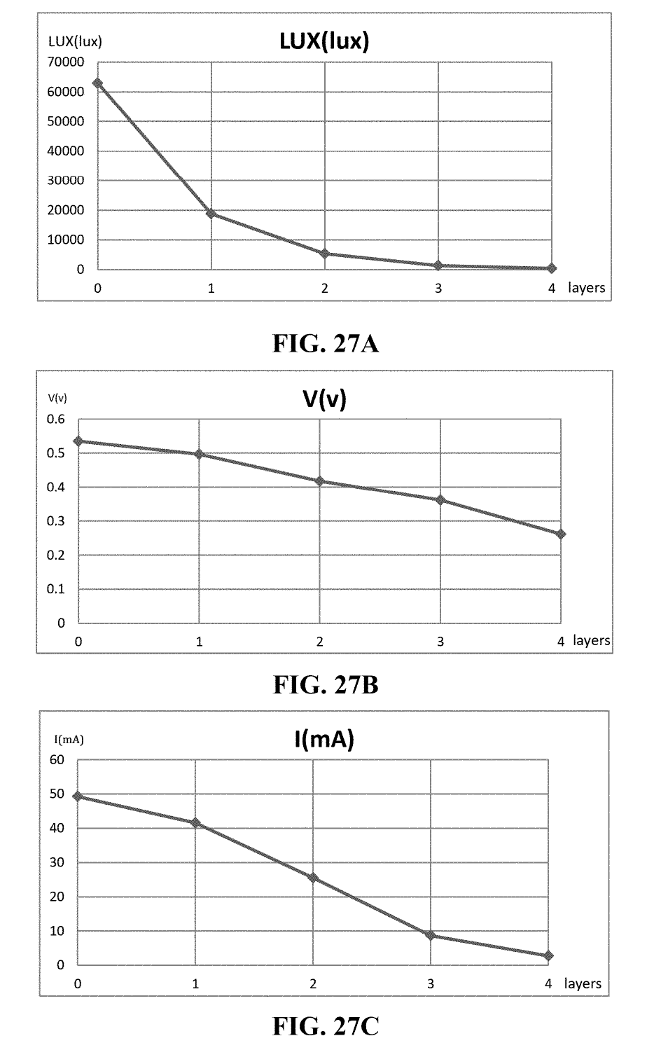

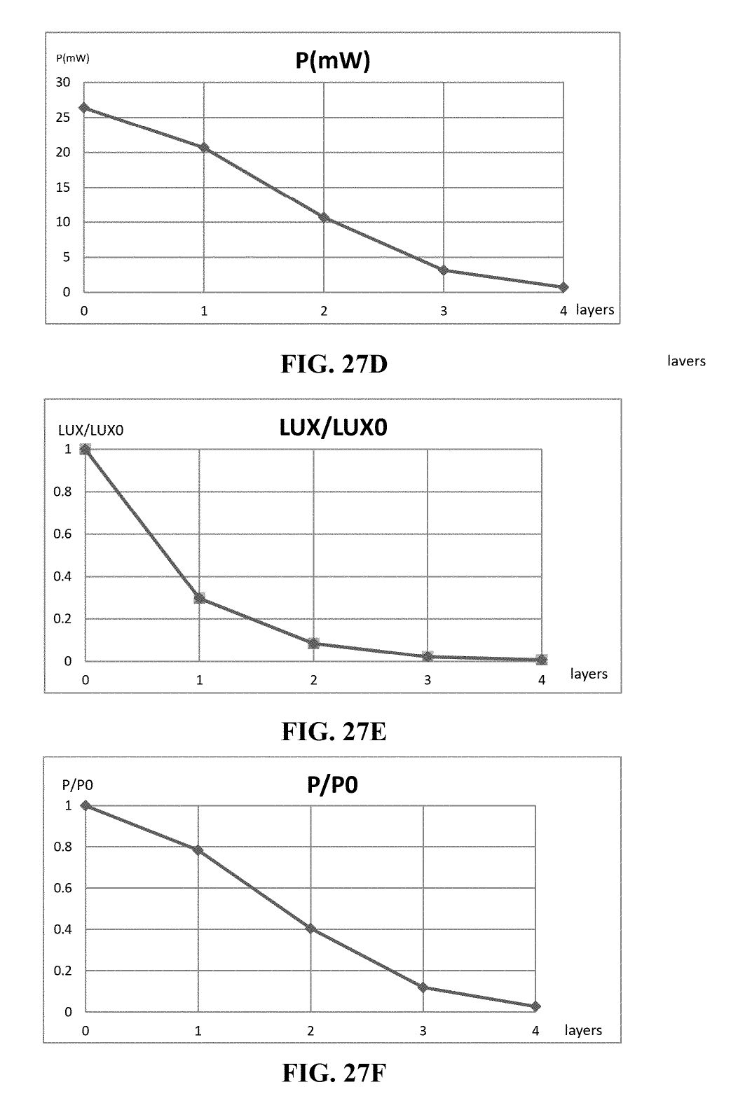

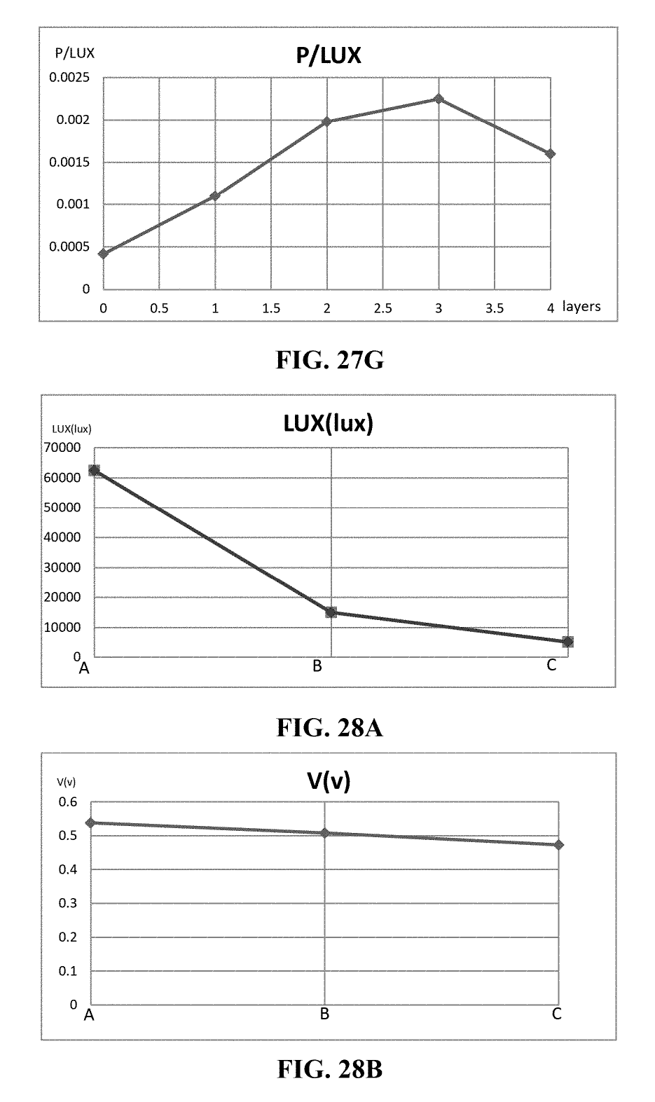

Under 64000±2000 lux, 33° C., we generate power by the structure including multiple solar cells as FIG. 26A. In this structure, each solar cell can transmit partial sun light. This technique integrates partial transmitting and partial transparent solar cell (unit 1212, 1222, 1232 and 1242, imitated by glass slide) and partial transmitting solar cell with transmitting holes (unit 1211, 1221, 1231 and 1241, imitated by screen panel as embodiment 1). The solar cell with transmitting holes can be made by the thin film technique or back etching technique of MEMS. Each of the second to fifth layers is composed of a screen panel and a glass with 0.950 of transmittance, to imitate mixed type partial transmitting light solar cell. The first layer is base solar cell. FIGS. 27A-27D show the measured illuminance, output voltage, current and power. In the figures, the label “0” in horizontal axis represents the measured value without covering glass slide and screen panel; the label “1” in horizontal axis represents the measured value with covering 1 set of a glass slide and a screen panel; the label “2” in horizontal axis represents the measured value with covering 2 set of a glass slide and a screen panel (a glass slide and a screen panel for each set); the label “3” in horizontal axis represents the measured value with covering 3 set of a glass slide and a screen panel (a glass slide and a screen panel for each set); the label “4” in horizontal axis represents the measured value with covering 4 set of a glass slide and a screen panel (a glass slide and a screen panel for each set). FIGS. 27A-27D and 27F show the result of illuminance, output voltage, current and power of the solar cell covered various layers. FIGS. 27E-27G show the ratios of LUX/LUX0, P/Po and P/LUX. The result shown the illuminance reduction ratio is much higher than the output power reduction ratio. The P/LUX increased with the layer number, except for the depression after adding the fourth layer. The reason is the LUX is reduce to 450 lux after covering the forth layer. We know P/LUX would reduce through the data of FIGS. 1A-1F. This embodiment proved this multiple layer structure including partial transmitting and partial transparent solar cell and partial transmitting solar cell with transmitting holes can improve total power generation amount.

### Embodiment 13

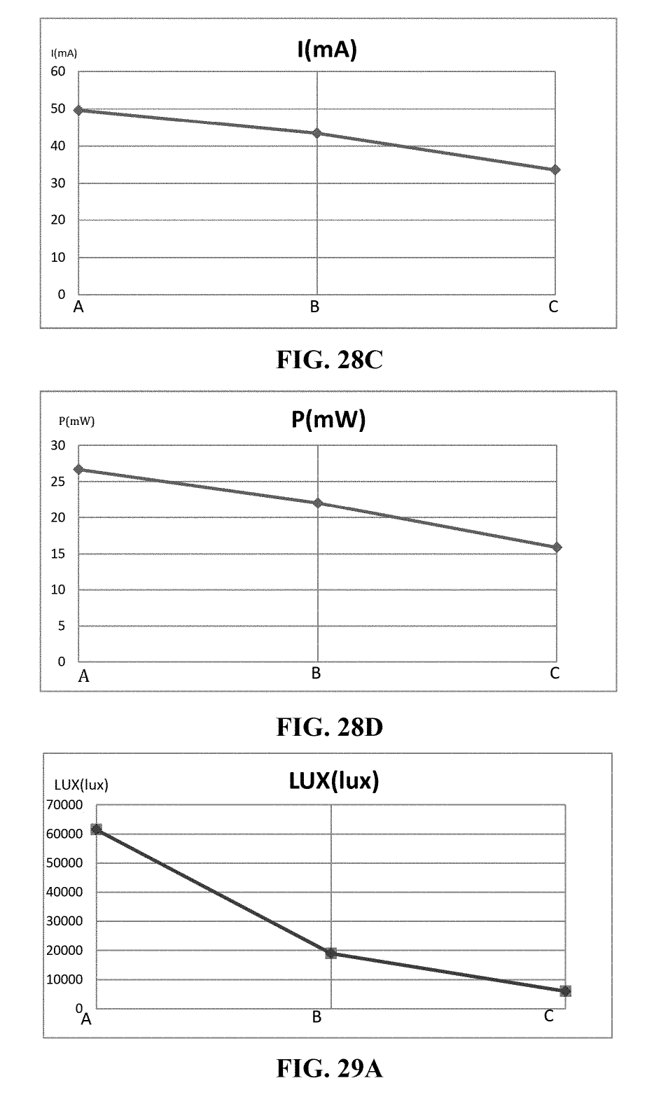

Under 62200±500 lux of light, we use a layer composed of glass slide and a screen panel to imitating mixed type partial transmitting light and partial transparent solar cell, as shown in FIG. 26B. The difference between this embodiment and the embodiment 12 is that the second layer covered on the base solar cell with a distance of 4 cm and the third layer covered on the base solar cell with a distance of 6 cm (a distance of 2 cm from the second layer. Each partial transparent layer is a glass slide with transmittance of 0.950 only. This embodiment describe integrating light partial transparent transmitting solar cell and solar cell with light transmitting holes and constructing 3D structure to improve total power generation amount on fixed erected area. FIGS. 28A-28D show the results of the output voltage, current and power of the solar cell. In the figures, the label “A” in horizontal axis represents adding no glass slide or screen penal; the label “B” represents the solar cell covered with a glass slide and a screen panel and has a distance of 4 cm from the base solar cell panel; the label “C” represents the solar cell covered with a glass slide and a screen panel and having a distance of 4 cm from the lower solar cell panel (the first layer) and further covered with a glass slide and a screen panel (the third layer) having a distance of 6 cm from the solar cell panel (the first layer) and having a distance of 2 cm from the solar cell panel (the second layer). The combination of a glass slide and a screen panel is used to imitate a partial transmitting light solar cell. The results proved the 3D structure also improve the power generation amount on fixed solar cell erected area.

### Embodiment 14

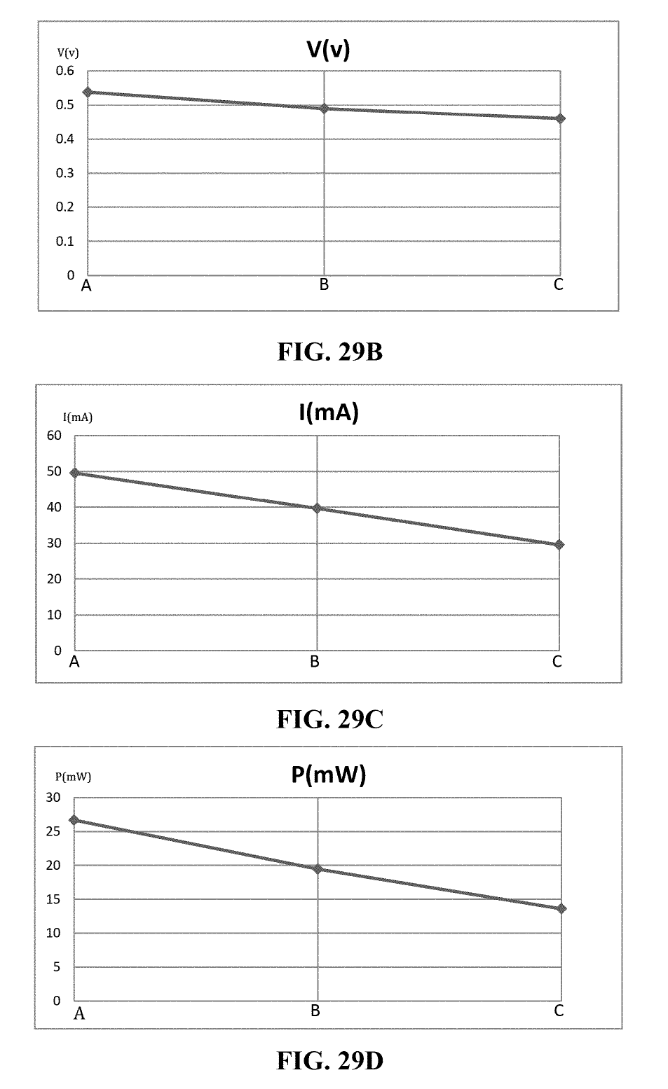

Under 62200±500 lux of light, we use six glass slides and one screen panels to be one layer (to imitate mixing light transmitting holes and partial transparent solar cell) to reduce light transmission, as shown as FIG. 26C. The difference between this embodiment and the embodiment 13 is that the second layer including one screen panel and six glass slides (to imitate combining solar cell with light transmitting holes and partial transparent solar cell) has a distance of 4 cm from the base (the first layer), and the third layer including one screen panel and six glass slides (to imitate combining solar cell with light transmitting holes and partial transparent solar cell) has a distance of 6 cm from the base (the first layer) and has a distance of 2 cm from the second layer. The measured illuminance, output voltage, current and power under various circumstances shown in FIGS. 29A-29D.

The power generation amount of the solar cell without glass slide and screen panel (the first layer) (labeled “A” in horizontal axis) are 0.538V and 49.6 mA. The power generation amount of the solar cell with one layer of six glass slides and a screen panel (the second layer) (labeled “B” in horizontal axis) are 0.490V and 39.7 mA. The power generation amount of the solar cell with two layers of six glass slides and a screen panel (six glass slides and a screen panel for each layer) (the third layer) (labeled “C” in horizontal axis) are 0.460V and 29.6 mA. The transmittance of the third layer is 15000/62500=0.24 and the transmittance of the second layer is 5200/15000=0.347. If we cover the second and third layer to generate power, the total power generation amount is 26.685×(1−0.24)+19.453×(1−0.347)+13.616×1=46.6 mW, which is much greater than the power generation amount of single solar cell.

The result proved that this 3D structure could improve the power generation amount on a fixed solar cell erected area. Although the structure takes more cost in solar cell, it still provides a method for improving the power generation amount of solar cell on limited light receiving area.

Furthermore, the present invention also provides a device or structure for improving power generation or power generation efficiency of solar cell on unit erected area 1, comprising a solar cell panel configured in an uneven shape. Compare with panel shape solar cell, the uneven shape solar cell can increase light receiving area on unit erected area; light received on the solar cell panel is scattered to bigger area of solar cell panel thus decreases in illuminance (compare with panel shape solar cell).

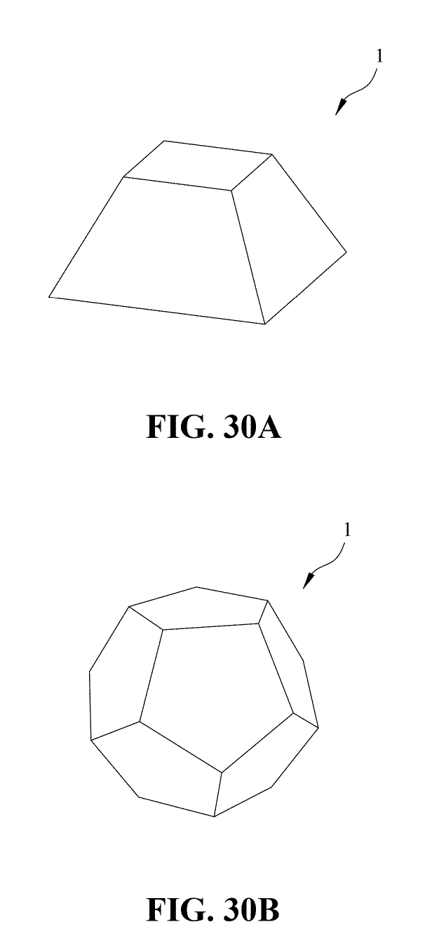

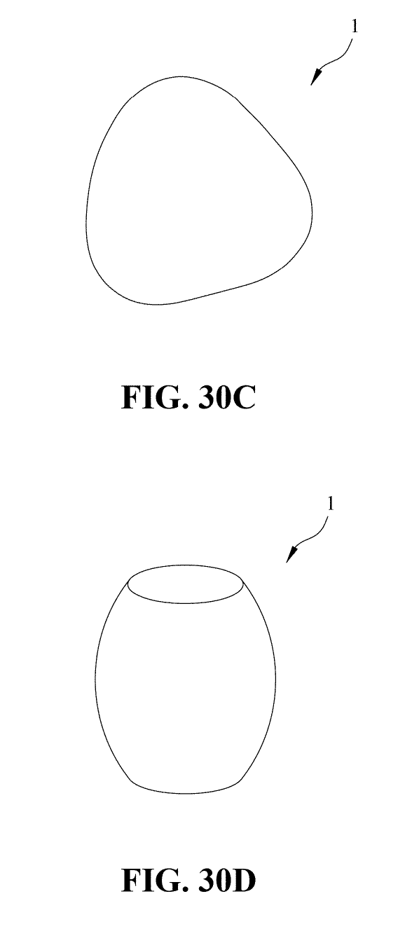

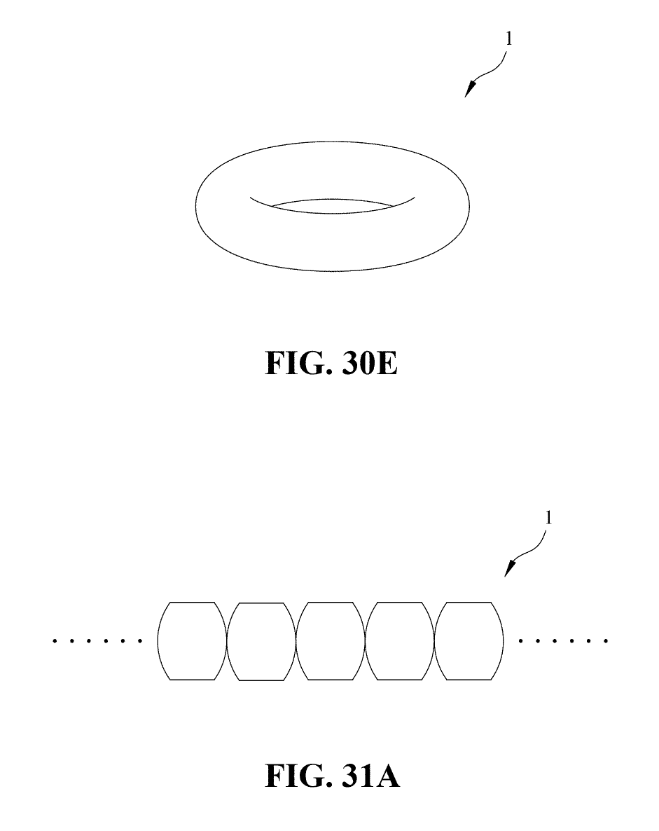

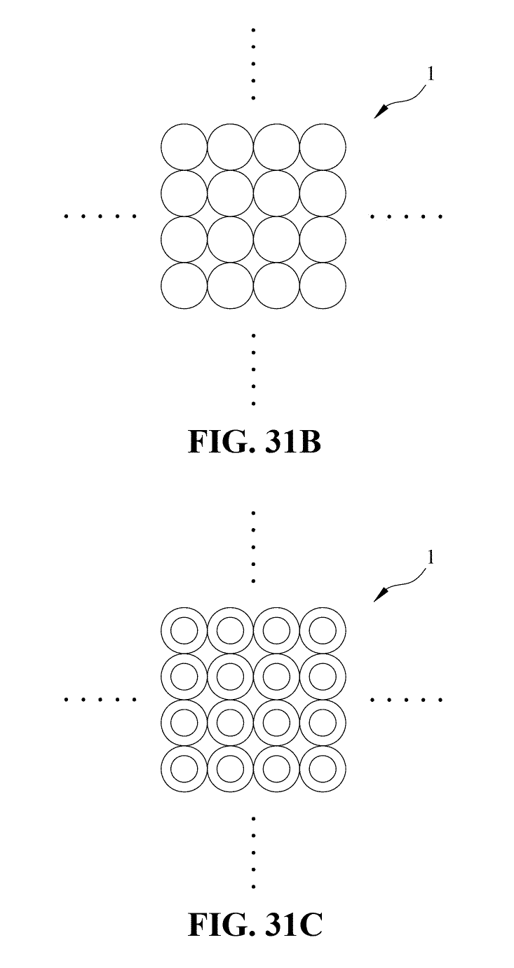

The uneven shape can be a shape of sin wave, a square wave, a triangular wave, a sphere, a cone, a column, a prismoid (as shown in FIG. 30A), a polyhedron (exemplary as shown in FIG. 30B), a curved body (exemplary as shown in FIG. 30C), a barrel (as shown in FIG. 30D), a ring (as shown in FIG. 30E, like the shape of a donut), or any combination thereof. The uneven shape solar cell can be extended out, such as in a periodic way, such as FIGS. 5A (sine wave), 5B (triangular wave) and 31A (barrel). The uneven shape solar cell can be extended out in an array arrangement way, such as FIGS. 31B (sphere) and 31C (ring).

Based on the embodiments 1-15 and the description above, we could understand a device comprising a base solar cell and a set of light transmitting solar cell. The set of light transmitting solar cell configured on a light receiving surface of the base solar cell; wherein the set of light transmitting solar cell comprises at least one light transmitting solar cell and the light transmitting solar cell has a partial light transmission property to improve total power generation amount. The base solar cell or any one solar cell of the set of light transmitting solar cell may has light transmitting holes, partial transparent property, uneven shape or combination thereof. The solar cells in the structure may have a distance from each other for further improving power generation amount. The output voltage, current and power of a solar cell received light is not a linear relationship with illuminance. Under high illuminance of sun light, the ratio of output voltage, current and power is lower than under low illuminance of sun light. Thus, the power generation efficiency of solar cell depressed while the light illuminance is too high. The present invention provides the method using increasing the surface area of solar cell on unit erected area to scatter sunlight to the solar cell which has bigger area, can increase the power generation amount of solar cell on unit erected area. Although the efficiency of various solar cell panels are similar to each other, we can improve the power generation amount on fixed erected area by including multiple solar cell or deploying tilted.

By the features of the present invention, the power generation or power generation efficiency is improved on fixed light receiving area. For solar cell power generation in a limited area, it is very practical for generating more power. For example, the solar cell outside the house, on the roof, inside the house, on a conveyance such as a car, a plane and a spacecraft and a portable device such as a mobile phone and a watch. The present invention has wide range of applications, thus increase the availability of solar power. The solar power plants can be installed at the same site and get more power output.

Moreover, the method of the present invention can get more power on smaller light receiving area. It is useful for the small device such as watch and cell phone or vehicle, airplane, boat, spacecraft and satellite. The solar cell is not limit to any solar cell, comprising a solar cell made of Si, GaAs, semiconductor material, organic material or inorganic material; or such as a p-n junction solar cell, a thin film solar cell or a thick film solar cell.

By the technical features of the present invention, we can use any solar cell to construct a 3D structure and improve the power generation amount on the fixed light receiving area.

1. A method for improving power generation of solar cell on unit erected area, comprising: providing a base solar cell and a set of light transmitting solar cell, the set of light transmitting solar cell is configured on a light receiving surface of the base solar cell; wherein the set of light transmitting solar cell comprises at least one light transmitting solar cell, and the light transmitting solar cell has a partial light transmission property.

2. The method according to claim 1, wherein a gap is between the base solar cell and the set of light transmitting solar cell.

3. The method according to claim 2, wherein the gap is at least 1 cm.

4. The method according to claim 1, wherein the set of light transmitting solar cell comprises at least two light transmitting solar cells; a gap is between each two light transmitting solar cells.

5. The method according to claim 4, wherein the gap is at least 1 cm.

6. The method according to claim 1, wherein the light transmitting solar cell has partial light transparent property, thereby having a partial light transmission property.

7. The method according to claim 1, wherein one of the at least one light transmitting solar cell has at least one light transmitting hole, and the light transmitting hole provides a partial light transmission property of the light transmitting solar cell.

8. The method according to claim 1, wherein one of the at least one light transmitting solar cell has a plurality of light transmitting holes, and the light transmitting holes provide a partial light transmission property of the light transmitting solar cell.

9. The method according to claim 1, wherein the base solar cell and the light transmitting solar cell are in panel shape or three-dimensional uneven shape.

10. The method according to claim 9, wherein the three-dimensional uneven shape comprises a shape of a sine wave, a square wave, a triangular wave, a sphere, a cone, a column, a prismoid, a polyhedron, a curved body, a barrel, a ring, or any combination thereof.

11. The method according to claim 9, wherein the three-dimensional uneven shape is extended out.

12. The method according to claim 9, wherein the three-dimensional uneven shape is extended out in a periodic way.

13. The method according to claim 9, wherein the three-dimensional uneven shape is extended out in an array arrangement way.

14. The method according to claim 7, wherein the light transmitting hole has a shape selected from the group consisting of circular, rhombic, polygonal, oval, rectangular, and irregularly shaped.

15. The method according to claim 1, wherein any one solar cell of the base solar cell and the set of light transmitting solar cell improves its power generation on unit erected area by sole or combination of the methods below: a method of the solar cell has partial light transparent property, thereby having partial light transmission property; a method of the solar cell has a light transmitting hole, thereby providing a partial light transmission property of the solar cell; a method of the solar cell has a plurality of light transmitting holes, thereby providing a partial light transmission property of the solar cell; a method of the solar cell is in panel shape or three-dimensional uneven shape.

16. The method according to claim 1, wherein the base solar cell or the light transmitting solar cell is made from a semiconductor material, an inorganic material or an organic material.

17. The method according to claim 16, wherein the semiconductor material is a silicon material or a compound semiconductor material.

18. The method according to claim 1, wherein the base solar cell or the light transmitting solar cell is a thin film solar cell or a thick film solar cell.

19. The method according to claim 1, further wetting or immersing the base solar cell and the set of light transmitting solar cell into a liquid.

20. The method according to claim 19, wherein a gap is between the base solar cell and the set of light transmitting solar cell.

21. The method according to claim 19, wherein the set of light transmitting solar cell comprises at least two light transmitting solar cells; a gap is between each two light transmitting solar cells.

22. The method according to claim 19, wherein any one solar cell of the base solar cell and the set of light transmitting solar cell improves its power generation on unit erected area by sole or combination of the methods below: a method of the solar cell has partial light transparent property, thereby having partial light transmission property; a method of the solar cell has a light transmitting hole, thereby providing a partial light transmission property of the solar cell; a method of the solar cell has a plurality of light transmitting holes, thereby providing a partial light transmission property of the solar cell; a method of the solar cell is in panel shape or three-dimensional uneven shape.

23. The method according to claim 22, wherein the light transmitting hole has a shape selected from the group consisting of circuler, rhombic, polygonal, oval, rectangular, and irregularly shaped.

24. The method according to claim 22, wherein the three-dimensional uneven shape comprises a shape of a sine wave, a square wave, a triangular wave, a sphere, a cone, a column, a prismoid, a polyhedron, a curved body, a barrel, a ring, or any combination thereof.

25. The method according to claim 22, wherein the three-dimensional uneven shape is extended out.

26. The method according to claim 19, wherein the liquid is seawater, water or aqueous solution.

27. The method according to claim 26, wherein a gap is between the base solar cell and the set of light transmitting solar cell.

28. The method according to claim 26, wherein the set of light transmitting solar cell comprises at least two light transmitting solar cells; a gap is between each two light transmitting solar cells.

29. The method according to claim 26, wherein any one solar cell of the base solar cell and the set of light transmitting solar cell improves its power generation on unit erected area by sole or combination of the methods below: a method of the solar cell has partial light transparent property, thereby having partial light transmission property; a method of the solar cell has a light transmitting hole, thereby providing a partial light transmission property of the solar cell; a method of the solar cell has a plurality of light transmitting holes, thereby providing a partial light transmission property of the solar cell; a method of the solar cell is in panel shape or three-dimensional uneven shape.

30. The method according to claim 29, wherein the light transmitting hole has a shape selected from the group consisting of circuler, rhombic, poly gonal, oval, rectangular, and irregularly shaped.

31. The method according to claim 29, wherein the three-dimensional uneven shape comprises a shape of a sine wave, a square wave, a triangular wave, a sphere, a cone, a column, a prismoid, a polyhedron, a curved body, a barrel, a ring, or any combination thereof.

32. The method according to claim 29, wherein the three-dimensional uneven shape is extended out.

33. A device for improving power generation of solar cell on unit erected area, comprising: a base solar cell and a set of light transmitting solar cell, the set of light transmitting solar cell is configured on a light receiving surface of the base solar cell; wherein the set of light transmitting solar cell comprises at least one light transmitting solar cell, and the light transmitting solar cell has a partial light transmission property.

34. The device according to claim 33, wherein a gap is between the base solar cell and the set of light transmitting solar cell.

35. The device according to claim 34, wherein the gap is at least 1 cm.

36. The device according to claim 33, wherein the set of light transmitting solar cell comprises at least two light transmitting solar cells; a gap is between each two light transmitting solar cells.

37. The device according to claim 36, wherein the gap is at least 1 cm.

38. The device according to claim 33, wherein the light transmitting solar cell has partial light transparent property, thereby having a partial light transmission property.

39. The device according to claim 33, wherein one of the at least one light transmitting solar cell has at least one light transmitting hole, and the light transmitting hole provides a partial light transmission property of the light transmitting solar cell.

40. The device according to claim 33, wherein one of the at least one light transmitting solar cell has a plurality of light transmitting holes, and the light transmitting holes provide a partial light transmission property of the light transmitting solar cell.

41. The device according to claim 33, wherein the base solar cell and the light transmitting solar cell are in panel shape or three-dimensional uneven shape.

42. The device according to claim 41, wherein the three-dimensional uneven shape comprises a shape of a sine wave, a square wave, a triangular wave, a sphere, a cone, a column, a prismoid, a polyhedron, a curved body, a barrel, a ring, or any combination thereof.

43. The device according to claim 41, wherein the three-dimensional uneven shape is extended out.

44. The device according to claim 41, wherein the three-dimensional uneven shape is extended out in a periodic way.

45. The device according to claim 41, wherein the three-dimensional uneven shape is extended out in an array arrangement way.

46. The device according to claim 39, wherein the light transmitting hole has a shape selected from the group consisting of circular, rhombic, polygonal, oval, rectangular, and irregularly shaped.

47. The device according to claim 33, wherein any one solar cell of the base solar cell and the set of light transmitting solar cell improves its power generation efficiency on unit erected area by sole or combination of the methods below: a method of the solar cell has partial light transparent property, thereby having a partial light transmission property; a method of the solar cell has a light transmitting hole, thereby providing a partial light transmission property of the solar cell; a method of the solar cell has a plurality of light transmitting holes, thereby providing a partial light transmission property of the solar cell; a method of the solar cell is in panel shape or three-dimensional uneven shape.

48. The device according claim 33, wherein the base solar cell and the light transmitting solar cell are independently made from a semiconductor material, an inorganic material or an organic material.

49. The device according claim 48, wherein the semiconductor material is a silicon material or a compound semiconductor material.

50. The device according to claim 33, wherein the base solar cell or the light transmitting solar cell is a thin film solar cell or a thick film solar cell.

51. The device according to claim 33, further comprising a container and a liquid, and the liquid is in the container and thereby the device is wetted or immersed into the liquid.

52. The device according to claim 51, wherein a gap is between the base solar cell and the set of light transmitting solar cell.

53. The device according to claim 51, wherein the set of light transmitting solar cell comprises at least two light transmitting solar cells; a gap is between each two light transmitting solar cells.

54. The device according to claim 51, wherein any one solar cell of the base solar cell and the set of light transmitting solar cell improves its power generation on unit erected area by sole or combination of the devices below: a device of the solar cell has partial light transparent property, thereby having partial light transmission property; a device of the solar cell has a light transmitting hole, thereby providing a partial light transmission property of the solar cell; a device of the solar cell has a plurality of light transmitting holes, thereby providing a partial light transmission property of the solar cell; a device of the solar cell is in panel shape or three-dimensional uneven shape.

55. The device according to claim 54, wherein the light transmitting hole has a shape selected from the group consisting of circuler, rhombic, poly gonal, oval, rectangular, and irregularly shaped.

56. The device according to claim 54, wherein the three-dimensional uneven shape comprises a shape of a sine wave, a square wave, a triangular wave, a sphere, a cone, a column, a prismoid, a polyhedron, a curved body, a barrel, a ring, or any combination thereof.

57. The device according to claim 54, wherein the three-dimensional uneven shape is extended out.

58. The device according to claim 51, wherein the liquid is seawater, water or aqueous solution.

59. The device according to claim 58, wherein a gap is between the base solar cell and the set of light transmitting solar cell.

60. The device according to claim 58, wherein the set of light transmitting solar cell comprises at least two light transmitting solar cells; a gap is between each two light transmitting solar cells.

61. The device according to claim 58, wherein any one solar cell of the base solar cell and the set of light transmitting solar cell improves its power generation on unit erected area by sole or combination of the devices below: a device of the solar cell has partial light transparent property, thereby having partial light transmission property; a device of the solar cell has a light transmitting hole, thereby providing a partial light transmission property of the solar cell; a device of the solar cell has a plurality of light transmitting holes, thereby providing a partial light transmission property of the solar cell; a device of the solar cell is in panel shape or three-dimensional uneven shape.

62. The device according to claim 61, wherein the light transmitting hole has a shape selected from the group consisting of circuler, rhombic, poly gonal, oval, rectangular, and irregularly shaped.

63. The device according to claim 61, wherein the three-dimensional uneven shape comprises a shape of a sine wave, a square wave, a triangular wave, a sphere, a cone, a column, a prismoid, a polyhedron, a curved body, a barrel, a ring, or any combination thereof.

64. The device according to claim 61, wherein the three-dimensional uneven shape is extended out.

65. A method for improving power generation of solar cell on unit erected area, comprising configuring a solar cell panel in a three-dimensional uneven shape; the three-dimensional uneven shape increases light receiving area on unit erected area; and the light received on the solar cell is scattered to a bigger area of the solar cell panel thus decreases in illuminance.

66. The method according to claim 65, wherein the three-dimensional uneven shape comprises a shape of a sine wave, a square wave, a triangular wave, a sphere, a cone, a column, a prismoid, a polyhedron, a curved body, a barrel, a ring, or any combination thereof.

67. The method according to claim 65, wherein the three-dimensional uneven shape is extended out.

68. The method according to claim 65, wherein the three-dimensional uneven shape is extended out in a periodic way.

69. The method according to claim 65, wherein the three-dimensional uneven shape is extended out in an array arrangement way.

70. The method according to any one of claim 65, wherein further wetting or immersing the solar cell into a liquid.

71. The method according to claim 57, wherein the liquid is seawater, water or aqueous solution.

72. A device for improving power generation of solar cell on unit erected area, comprising a solar cell configured in a three-dimensional uneven shape; the three-dimensional uneven shape increases light receiving area on unit erected area; and light received on the solar cell is scattered to a bigger area of the solar cell thus decreases in illuminance.

73. The device according to claim 72, wherein the three-dimensional uneven shape comprises a shape of a sine wave, a square wave, a triangular wave, a sphere, a cone, a column, a prismoid, a polyhedron, a curved body, a barrel, a ring, or any combination thereof.

74. The device according to claim 72, wherein the three-dimensional uneven shape is extended out.

75. The device according to claim 72, wherein the three-dimensional uneven shape is extended out in a periodic way.

76. The device according to claim 72, wherein the three-dimensional uneven shape is extended out in an array arrangement way.

77. The device according to any one of claim 72, further comprising a container and a liquid, the liquid is in the container and thereby the base solar cell and the set of light transmitting solar cell are wetted or immersed into the liquid.

78. The device according to claim 77, wherein the liquid is seawater, water or aqueous solution.
